(19) United States
(12) Patent Application Publication
(10) Pub. No.: US 2026/0231445 A1
(43) Pub. Date: Aug. 6, 2026

(54) SEMICONDUCTOR DEVICE

(71) Applicant: Samsung Electronics Co., Ltd., Suwon-si (KR)

(72) Inventors: Sujin Kang, Suwon-si (KR); Hui-Jung Kim, Suwon-si (KR); Hyunjin Lee, Suwon-si (KR); Yong Kwan Kim, Suwon-si (KR)

(21) Appl. No.: 19/304,446

(22) Filed: Aug. 19, 2025

(30) Foreign Application Priority Data
Jan. 31, 2025 (KR) 10-2025-0012713

(51) Int. Cl. H10D 1/68; H10B 12/00

(52) U.S. Cl. CPC H10D 1/714; H10B 12/482; H10B 12/488; H10B 12/03; H10B 12/05

(57) ABSTRACT

A semiconductor device comprises a substrate, a plurality of semiconductor patterns stacked spaced apart from each other on the substrate, a bit line connected to a first end portion of the plurality of semiconductor patterns in a first direction, and extending in a direction perpendicular to an upper surface of the substrate, a word line overlapping each semiconductor pattern in the plurality of semiconductor patterns in the direction perpendicular to the upper surface of the substrate, and extending in a second direction intersecting the first direction, a capacitor connected to a second end portion of each semiconductor pattern in the plurality of semiconductor patterns in the first direction, a metal silicide pattern between each semiconductor pattern and the capacitor, and an intermediate insulating layer overlapping the metal silicide pattern in the direction perpendicular to the upper surface of the substrate.

### CROSS-REFERENCE TO RELATED APPLICATION

Pursuant to 35 U.S.C. § 119(a), this application claims the benefit of an earlier filing date and right of priority to Korean Patent Application No. 10-2025-0012713 filed with the Korean Intellectual Property Office on Jan. 31, 2025, the entire contents of which are incorporated herein by reference.

### TECHNICAL FIELD

The present disclosure relates to semiconductor devices.

### BACKGROUND

There is a growing demand for technologies that increase the integration density of semiconductor devices. In the case of a two-dimensional semiconductor device, the integration density is mainly determined by the area occupied by a unit memory cell, and this integration density may depend on the level of fine patterning technology.

However, fine patterning technology requires expensive equipment, so although the integration density of two-dimensional semiconductor devices has been increasing, it still remains limited. Accordingly, three-dimensional semiconductor memory devices, in which memory cells are arranged in a three-dimensional structure, have been proposed.

### SUMMARY

Some aspects of the present disclosure provide a semiconductor device with improved element characteristics.

A semiconductor device according to some implementations comprises a substrate, a plurality of semiconductor patterns stacked to be spaced apart from each other on the substrate, a bit line connected to a first end portion of the plurality of semiconductor patterns in a first direction, and extending in a direction perpendicular to the upper surface of the substrate, a word line overlapping each semiconductor pattern in the plurality of semiconductor patterns in the direction perpendicular to the upper surface of the substrate, and extending in a second direction intersecting the first direction, a capacitor connected to a second end portion of each semiconductor pattern in the plurality of semiconductor patterns in the first direction, a metal silicide pattern between each semiconductor pattern and the capacitor, and an intermediate insulation layer overlapping the metal silicide pattern in the direction perpendicular to the upper surface of the substrate.

A semiconductor device according to some implementations comprises a substrate, a plurality of semiconductor patterns stacked to be spaced apart from each other on the substrate, a bit line connected to a first portion of the plurality of semiconductor patterns in a first direction, and extending in a direction perpendicular to an upper surface of the substrate, a word line overlapping each semiconductor pattern in the plurality of semiconductor patterns in the direction perpendicular to the upper surface of the substrate, and extending in a second direction intersecting the first direction, a capacitor connected to a second end portion of each semiconductor pattern in the plurality of semiconductor patterns in the first direction, a metal silicide pattern between each semiconductor pattern and the capacitor, and an intermediate insulating layer surrounding the metal silicide pattern.

A semiconductor device according to some implementations comprises a substrate, an intermediate insulating layer extending in a direction perpendicular to an upper surface of the substrate, a plurality of metal silicide patterns spaced apart by the intermediate insulating layer, a plurality of semiconductor patterns respectively connected to a first side surface of the plurality of metal silicide patterns in a first direction, a bit line connected to a first end portion of the plurality of semiconductor patterns in the first direction, and extending in the direction perpendicular to the upper surface of the substrate, a plurality of word lines respectively adjacent to the plurality of semiconductor patterns, and extending in a second direction intersecting the first direction, and a plurality of capacitors respectively connected to a second side surface of the plurality of metal silicide patterns in the first direction, wherein the intermediate insulating layer is on two opposite sides of each of the plurality of metal silicide patterns in the second direction and on two opposite sides of each of the plurality of metal silicide patterns in the direction perpendicular to the upper surface of the substrate.

A method of manufacturing a semiconductor device according to some implementations may include forming a preliminary intermediate insulating layer which penetrates a plurality of first semiconductor layers and a plurality of second semiconductor layers on a substrate in a direction perpendicular to an upper surface of the substrate, forming a cell isolation insulating layer which penetrates the plurality of first semiconductor layers and the plurality of second semiconductor layers in the direction perpendicular to the upper surface of the substrate and separates in a first direction parallel to the upper surface of the substrate and a second direction intersecting the first direction on the substrate, removing the plurality of first semiconductor layers and thinning the plurality of second semiconductor layers to form a plurality of semiconductor patterns that are spaced apart and stacked in a third direction perpendicular to the upper surface of the substrate, removing a portion of the preliminary intermediate insulating layer to expose one end portion of the plurality of semiconductor patterns in the first direction, forming a plurality of sacrificial metal silicide patterns covering one end portion of the plurality of semiconductor patterns in the first direction, and forming an intermediate insulating layer overlapping the plurality of sacrificial metal silicide patterns in the third direction.

The cell isolation insulating layer may include an intermediate cell isolation insulating layer positioned on one side surface of the intermediate insulating layer in the first direction and a side cell isolation insulating layer positioned on the other side surface of the intermediate insulating layer in the first direction. The plurality of semiconductor patterns may include a plurality of first semiconductor patterns positioned on one side surfaces of the plurality of sacrificial metal silicide patterns in the first direction and a plurality of second semiconductor patterns positioned on the other side surfaces of the plurality of sacrificial metal silicide patterns in the first direction. The method of manufacturing the semiconductor device may further include the step of etching the intermediate cell isolation insulating layer until one side surface of the intermediate insulating layer in the first direction is exposed to expose the plurality of first semiconductor patterns, the step of forming a word line on the plurality of first semiconductor patterns, and the step of forming a bit line connected to one end portion of the plurality of first semiconductor patterns in the first direction.

The method of manufacturing the semiconductor device may include etching the side cell isolation layer until the other side surface of the intermediate insulating layer in the first direction is exposed to expose the plurality of second semiconductor patterns, forming a capacitor mold between the plurality of second semiconductor patterns, removing the plurality of second semiconductor patterns, and removing the plurality of sacrificial metal silicide patterns to expose the other end portion of the plurality of first semiconductor patterns in the first direction.

The method of manufacturing the semiconductor device may include forming a plurality of metal silicide patterns covering the other end portion of the plurality of first semiconductor patterns in the first direction, and forming a plurality of capacitors on the plurality of metal silicide patterns.

Each of the plurality of metal silicide patterns may be positioned between the capacitor and the semiconductor pattern, and may overlap with the intermediate insulating layer in the third direction. Each of the plurality of metal silicide patterns may further overlap with the intermediate insulating layer in the second direction.

In some implementations, both side surfaces of each of the plurality of metal silicide patterns in the third direction and both side surfaces of each of the plurality of metal silicide patterns in the second direction may contact the intermediate insulating layer.

In some implementations, the width of each of the plurality of metal silicide patterns in the third direction may be identical to the width of each of the plurality of first semiconductor patterns in the third direction. The width of each of the plurality of metal silicide patterns in the second direction may be identical to the width of each of the plurality of first semiconductor patterns in the second direction.

In some implementations, the width of each of the plurality of metal silicide patterns in the first direction may be smaller than the width of the intermediate insulating layer in the first direction.

The step of forming the plurality of capacitors may include forming a plurality of first electrodes on the plurality of metal silicide patterns, removing the capacitor mold, and forming a dielectric layer and a second electrode covering the plurality of first electrodes.

According to implementations, the element characteristics of a semiconductor device may be improved.

### BRIEF DESCRIPTION OF THE DRAWINGS

FIG. 1 is a plan view of a semiconductor device according to some implementations.

FIG. 2 is a cross-sectional view of a semiconductor device according to some implementations, taken along line A-A′ of FIG. 1.

FIG. 3 is a cross-sectional view of a semiconductor device according to some implementations, taken along line B-B′ of FIG. 1.

FIG. 4 is a cross-sectional view of a semiconductor device according to some implementations, taken along the line C-C′ of FIG. 1.

FIG. 5 is an enlarged sectional view of the P region of FIG. 2.

FIG. 6 and FIG. 7 are enlarged sectional views of a semiconductor device according to some implementations.

FIG. 8 and FIG. 9 are cross-sectional views of a semiconductor device according to some implementations.

FIG. 10 to FIG. 57 are diagrams illustrating a manufacturing process of a semiconductor device according to some implementations in sequence.

### DETAILED DESCRIPTION

Hereinafter, the various implementations of the present disclosure will be described in detail with reference to the accompanying drawings, so that those skilled in the art to which the present disclosure pertains may easily implement them. The present disclosure may be embodied in various different forms and is not limited to the implementations described herein.

For clarity of description in the disclosure, parts unrelated to the description may have been omitted, and the same reference numerals may be assigned to the same or similar elements throughout the disclosure.

Additionally, the sizes and thicknesses of each component shown in the drawing are depicted arbitrarily for the sake of explanation, and thus, the present disclosure is not limited to the illustrations. In the drawing, the thickness is enlarged to clearly express the multiple layers and regions. In the drawing, for the sake of explanation, the thickness of some layers and regions is depicted exaggeratedly.

When a layer, a film, a region, a plate, or the like is said to be “on” or “above” another part, it includes not only the case of being directly on another part but also the case where another part is intervening. Conversely, when a part is said to be directly “on” another part, it means that there is no other part in between. Additionally, when it is said to be “on” or “above” a reference part, it may be positioned above or below the reference part and does not necessarily mean being “on” or “above” in the direction opposite to gravity.

Throughout the disclosure, when a part is said to “include” an element, it means that unless specifically stated otherwise, other elements may be further included, rather than excluding other elements.

Throughout the disclosure, when referring to “plan view,” it means viewing the target part from above, and when referring to “cross-sectional view,” it means viewing a vertical cross-section of the target part from the side.

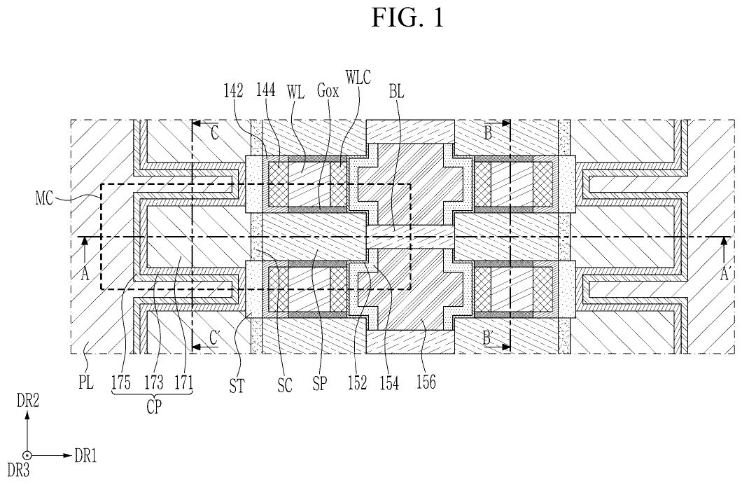

Referring to FIG. 1 to FIG. 5, a semiconductor device according to some implementations will be described.

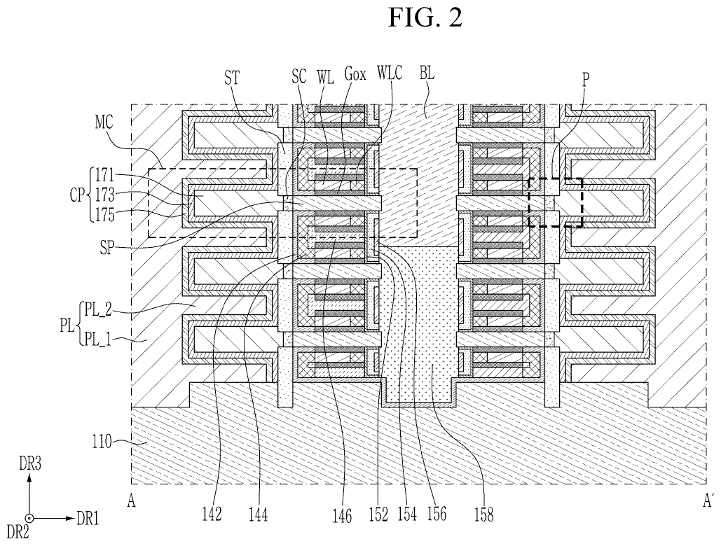

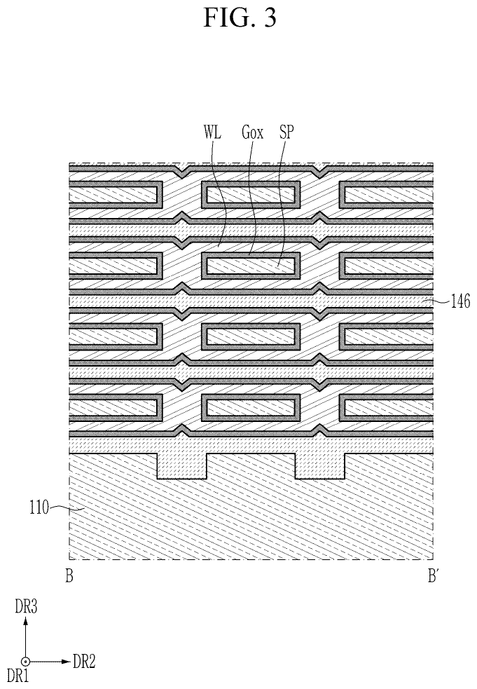

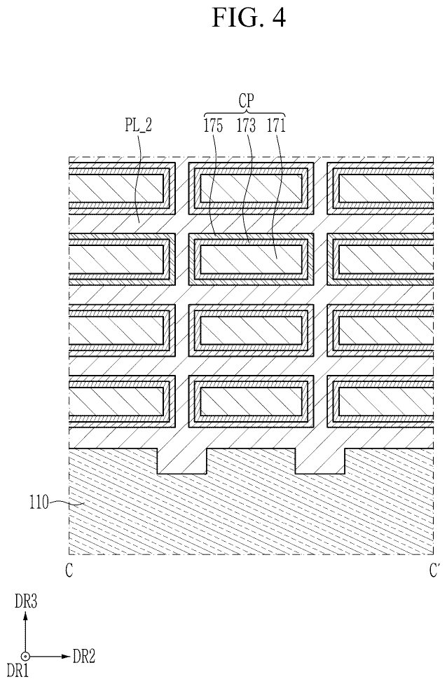

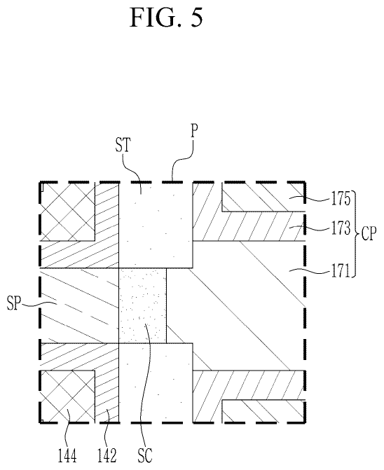

FIG. 1 is a plan view of a semiconductor device according to some implementations. FIG. 2 is a cross-sectional view of the semiconductor device according to some implementations, taken along line A-A′ of FIG. 1. FIG. 3 is a cross-sectional view of the semiconductor device according to some implementations, taken along line B-B′ of FIG. 1. FIG. 4 is a cross-sectional view of the semiconductor device according to some implementations, taken along line C-C′ of FIG. 1. FIG. 5 is an enlarged sectional view of the P region of FIG. 2.

Referring to FIG. 1 to FIG. 5, a semiconductor device according to some implementations includes a substrate 110, a plurality of semiconductor patterns SP stacked to be spaced apart from each on the substrate 110, a bit line BL connected to one end portion of the plurality of semiconductor patterns SP in a first direction DR1 and extending in a direction perpendicular to an upper surface of the substrate 110, a word line WL overlapping each of the plurality of semiconductor patterns SP in the direction (e.g., a third direction DR3) perpendicular to the upper surface of the substrate 110 and extending in a second direction DR2 that intersects the first direction DR1, a capacitor CP connected to the other end portion of each of the plurality of semiconductor patterns SP in the first direction DR1, a metal silicide pattern SC positioned between the semiconductor pattern SP and the capacitor CP, and an intermediate insulating layer ST overlapping the metal silicide pattern SC in the third direction DR3. As used herein, “extending” includes “being elongated” or “being oriented along.” For example, “extending in a second direction” includes “being elongated in a second direction” or “being oriented along a second direction.”

The substrate 110 may include a semiconductor material. For example, the substrate 110 may include Group IV semiconductors, Group III-V compound semiconductors, Group II-VI compound semiconductors, etc. For instance, the substrate 110 may include semiconductors such as Si and Ge, or compound semiconductors such as SiGe, SiC, GaAs, InAs, or InP. For example, the substrate 110 may be an epitaxial layer grown on a monocrystalline silicon substrate. However, the material of the substrate 110 is not limited thereto and may be varied diversely.

The plurality of semiconductor patterns SP may be stacked on the substrate 110 spaced apart from each other. The plurality of semiconductor patterns SP may be stacked to be spaced apart in the third direction DR3 that is perpendicular to the upper surface of the substrate 110. The plurality of semiconductor patterns SP may be arranged spaced apart in the first direction DR1 parallel to the upper surface of the substrate 110. In some implementations, two adjacent semiconductor patterns SP in the first direction DR1 may have a symmetrical structure with reference to the bit line BL, but this is not limiting. The plurality of semiconductor patterns SP may be arranged spaced apart in the second direction DR2 intersecting the first direction DR1. The second direction DR2 may be a direction parallel to the upper surface of the substrate 110. For example, the second direction DR2 may be a direction perpendicular to the first direction DR1.

The semiconductor pattern SP may extend in the first direction DR1. The semiconductor pattern SP may have a rod shape extending in the first direction DR1. One end portion of the semiconductor pattern SP along the first direction DR1 may be connected to the bit line BL. For example, the semiconductor pattern SP may contact the bit line BL, but is not limited thereto. A predetermined other layer may also be positioned between the semiconductor pattern SP and the bit line BL. At least one semiconductor pattern SP among the plurality of semiconductor patterns SP adjacent to the upper surface of the substrate 110 may not be connected to the bit line BL. At least one semiconductor pattern SP adjacent to the upper surface of the substrate 110 may contact a lower insulating layer 158 which will be described later. The other end portion of the semiconductor pattern SP in the first direction DR1 may be connected to the capacitor CP. The metal silicide pattern SC may be positioned between the semiconductor pattern SP and the capacitor CP.

The semiconductor pattern SP may include a semiconductor material. For example, the semiconductor pattern SP may include silicon, germanium, or silicon-germanium. In one example, the semiconductor pattern SP may include monocrystalline silicon or polycrystalline silicon. However, implementations are not limited thereto.

The word line WL may be positioned adjacent to the semiconductor pattern SP. The word line WL may be spaced apart from the semiconductor pattern SP by the gate insulating layer Gox. The word line WL may overlap with the semiconductor pattern SP in the third direction DR3. In some implementations, the word line WL may surround the semiconductor pattern SP. The word line WL may surround a part of the outer circumferential surface centered around the first direction DR1 of the semiconductor pattern SP. The word line WL may surround the part between both ends of the semiconductor pattern SP in the first direction DR1. A channel may be formed along the surface of the semiconductor pattern SP surrounded by the word line WL.

However, it is not limited to the aforementioned implementations. For example, the word line WL may overlap with the semiconductor pattern SP only in the third direction DR3 and may not overlap in the second direction DR2. For instance, one word line WL may be positioned on one side surface of the semiconductor pattern SP along the third direction DR3. As another example, two word lines WL may each be positioned on both sides of the semiconductor pattern SP along the third direction DR3.

The word line WL may extend in the second direction DR2. The word line WL extending in the second direction DR2 may be electrically connected to the plurality of semiconductor patterns SP that are arranged spaced apart in the second direction DR2. In some implementations, the word line WL may surround the plurality of semiconductor patterns SP arranged in the second direction DR2 and extend in the second direction DR2.

The semiconductor device according to some implementations may include a plurality of word lines WL. The plurality of word lines WL may be stacked to be spaced apart from each other in the third direction DR3. Each of the plurality of word lines WL stacked in the third direction DR3 may be electrically connected with each of the plurality of semiconductor patterns SP stacked in the third direction DR3. In some implementations, each of the plurality of word lines WL stacked in the third direction DR3 may surround each of the plurality of semiconductor patterns SP stacked in the third direction DR3. The plurality of word lines WL may be positioned spaced apart from each other in the first direction DR1. In some implementations, two adjacent word lines WL in the first direction DR1 may have a symmetrical structure with reference to the bit line BL, but are not limited thereto.

The word line WL may include conductive materials. For example, the word line WL may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or combinations thereof.

The gate insulating layer Gox may be positioned between the word line WL and the semiconductor pattern SP. The gate insulating layer Gox may be positioned between the word line WL and the later-described third interlayer dielectric layer 146.

The gate insulating layer Gox may include at least one of a high-k material, silicon oxide, silicon nitride, or silicon oxynitride. The high-k material may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The word line capping layer WLC may be positioned on one end portion of the word line WL in the first direction DR1. The word line capping layer WLC may cover one side surface of the word line WL in the first direction DR1. The word line capping layer WLC may be positioned between the word line WL and the bit line BL, and between the word line WL and the lower insulating layer 158 described later. In some implementations, a gate insulating layer Gox may be positioned between the word line capping layer WLC and the semiconductor pattern SP, but is not limited thereto. For example, the word line capping layer WLC may also be positioned directly on the semiconductor pattern SP.

The word line capping layer WLC may include an insulating material. For example, the word line capping layer WLC may include silicon nitride, but is not limited thereto.

In some implementations, a first interlayer dielectric layer 142, a second interlayer dielectric layer 144, and a third interlayer dielectric layer 146 may be positioned between the plurality of semiconductor patterns SP stacked in the third direction DR3. The first interlayer dielectric layer 142, the second interlayer dielectric layer 144, and the third interlayer dielectric layer 146 may be sequentially stacked on the plurality of semiconductor patterns SP. The first interlayer dielectric layer 142 and the second interlayer dielectric layer 144 may be positioned on both sides of the semiconductor patterns SP in the first direction DR1. For example, the first interlayer dielectric layer 142 and the second interlayer dielectric layer 144 may surround the other end portion of the semiconductor patterns SP in the first direction DR1. The first interlayer dielectric layer 142 and the second interlayer dielectric layer 144 may cover both side surfaces in the second direction DR2 and both side surfaces in the third direction DR3 of the other end portion of the semiconductor patterns SP in the first direction DR1. The first interlayer dielectric layer 142 may further cover the upper surface of the substrate 110. The second interlayer dielectric layer 144 may cover the other side surface of the word line WL in the first direction DR1. The third interlayer dielectric layer 146 may be positioned between two adjacent word lines WL. The third interlayer dielectric layer 146 may cover the facing surfaces in the third direction DR3 of two adjacent word lines WL. The gate insulating layer Gox may be positioned between the third interlayer dielectric layer 146 and the word line WL.

The first interlayer dielectric layer 142, the second interlayer dielectric layer 144, and the third interlayer dielectric layer 146 may include an insulating material. For example, the first interlayer dielectric layer 142, the second interlayer dielectric layer 144, and the third interlayer dielectric layer 146 each may include silicon oxide or silicon nitride, but are not limited thereto. The second interlayer dielectric layer 144 may include a material having an etch selectivity relative to a material of the first interlayer dielectric layer 142. The third interlayer dielectric layer 146 may include a material having an etch selectivity relative to a material of the second interlayer dielectric layer 144. For example, the first interlayer dielectric layer 142 and the third interlayer dielectric layer 146 may include silicon oxide, and the second interlayer dielectric layer 144 may include silicon nitride, but are not limited thereto.

FIG. 2 shows an interlayer dielectric layer between the plurality of semiconductor patterns SP stacked in the third direction DR3 as a triple layer, but the implementation is not limited thereto. For example, the number of layers of the interlayer dielectric layer between the plurality of semiconductor patterns SP stacked in the third direction DR3 may vary.

The bit line BL may extend in the third direction DR3 on the substrate 110. For example, the bit line BL may have a column shape extending in the third direction DR3, but it is not limited thereto. The first interlayer dielectric layer 142 and the lower insulating layer 158, to be described later, may be positioned between the lower surface of the bit line BL and the upper surface of the substrate 110. The bit line BL may be insulated from the substrate 110 by the first interlayer dielectric layer 142 and the lower insulating layer 158.

The bit line BL may be connected to the plurality of semiconductor patterns SP stacked in the third direction DR3. The bit line BL may be connected to one end portion of the plurality of semiconductor patterns SP stacked in the third direction DR3. The bit line BL may be positioned between two semiconductor patterns SP spaced apart in the first direction DR1. In some implementations, one bit line BL may be connected to two semiconductor patterns SP spaced apart in the first direction DR1, but is not limited thereto. For example, two semiconductor patterns SP spaced apart in the first direction DR1 may be connected to different bit lines BL.

The semiconductor device according to some implementations may include a plurality of bit lines BL. The plurality of bit lines BL may be spaced apart from each other and positioned in the second direction DR2. An isolation insulating layer 156, which will be described later, may be positioned between the plurality of bit lines BL spaced apart in the second direction DR2. Each of the plurality of bit lines BL spaced apart in the second direction DR2 may be connected to one end portion of each of the plurality of semiconductor patterns SP in the first direction DR1. The plurality of semiconductor patterns SP may be spaced apart in the second direction DR2. Although not illustrated, the plurality of bit lines BL may be further positioned and spaced apart from each other in the first direction DR1.

The bit line BL may include a conductive material. For example, the bit line BL may include doped semiconductor material such as doped silicon or doped germanium, conductive metal nitrides such as titanium nitride or tantalum nitride, metals such as tungsten, titanium, or tantalum, metal-semiconductor compounds such as tungsten silicide, cobalt silicide, or titanium silicide, or combinations thereof.

A first insulating liner 152 and a second insulating liner 154 may be positioned on the semiconductor pattern SP, the gate insulating layer Gox, the word line capping layer WLC, and the third interlayer dielectric layer 146. The first insulating liner 152 and the second insulating liner 154 may be positioned between the plurality of bit lines BL spaced apart in the second direction DR2. The first insulating liner 152 and the second insulating liner 154 may surround one end portion of the plurality of semiconductor patterns SP in the first direction DR1. The first insulating liner 152 and the second insulating liner 154 may not be positioned between the semiconductor pattern SP and the bit line BL. The first insulating liner 152 and the second insulating liner 154 may cover both sides of one end portion in the first direction DR1 of the semiconductor pattern SP in the second direction DR2 and both sides of one end portion in the first direction DR1 of the semiconductor pattern SP in the third direction DR3. In some implementations, the first insulating liner 152 and the second insulating liner 154 may cover a portion of one side surface of the semiconductor pattern SP in the first direction DR1. The first insulating liner 152 and the second insulating liner 154 may cover the portion of one side surface of the semiconductor pattern SP in the first direction DR1 excluding the portion connected to the bit line BL. However, the implementations are not limited thereto. For example, the entire one side surface of the semiconductor pattern SP in the first direction DR1 may be connected to the bit line BL, and the first insulating liner 152 and the second insulating liner 154 may not cover one side surface of the semiconductor pattern SP in the first direction DR1.

FIG. 1 and FIG. 2 illustrate an insulated liner positioned between the word line WL and the bit line BL of a semiconductor device according to some implementations as being a double layer, but the implementation is not limited thereto. For example, the insulated liner may be a single layer or more than a triple layer.

The isolation insulating layer 156 may be positioned on the second insulating liner 154. The isolation insulating layer 156 may be positioned between a plurality of bit lines BL spaced apart in the second direction DR2. The isolation insulating layer 156 may cover surfaces of two adjacent bit lines BL facing each other in the second direction DR2. By the isolation insulating layer 156, the plurality of bit lines BL may be spaced apart and insulated. In some implementations, a portion of the isolation insulating layer 156 may be positioned between two semiconductor patterns SP adjacent in the first direction DR1, and between two semiconductor patterns SP adjacent in the second direction DR2, but is not limited thereto.

The first insulating liner 152, the second insulating liner 154, and the isolation insulating layer 156 may include an insulating material. For example, each of the first insulating liner 152, the second insulating liner 154, and the isolation insulating layer 156 may include silicon oxide or silicon nitride, but is not limited thereto. The second insulating liner 154 may include a material having an etch selectivity with respect to a material of the first insulating liner 152. The isolation insulating layer 156 may include a material having an etch selectivity with respect to a material of the second insulating liner 154. For example, the first insulating liner 152 and the isolation insulating layer 156 may include silicon oxide, and the second insulating liner 154 may include silicon nitride, but is not limited thereto.

In some implementations, the first insulating liner 152, the second insulating liner 154, and the isolation insulating layer 156 may be positioned between the word line WL and the bit line BL between the plurality of semiconductor patterns SP stacked in the third direction DR3. The first insulating liner 152, the second insulating liner 154, and the isolation insulating layer 156 may cover one side surface of the gate insulating layer Gox along the first direction DR1, one side surface of the word line capping layer WLC along the first direction DR1, and one side surface of the third interlayer dielectric layer 146 along the first direction DR1, between the plurality of semiconductor patterns SP stacked in the third direction DR3. However, the implementations are not limited thereto. For example, the isolation insulating layer 156 may not be positioned between the second insulating liner 154 and the bit line BL.

The lower insulating layer 158 may be positioned on a portion of the first interlayer dielectric layer 142 covering the upper surface of the substrate 110. The lower insulating layer 158 may be positioned between the bit line BL and the first interlayer dielectric layer 142. The lower insulating layer 158 may cover one side surface of at least one semiconductor pattern SP in the first direction DR1. The at least one semiconductor pattern SP may be adjacent to the upper surface of the substrate 110. The lower insulating layer 158 may cover one side surface of the first insulating liner 152, one side surface of the second insulating liner 154, and one side surface of the isolation insulating layer 156 in the first direction DR1. The first insulating liner 152, the second insulating liner 154, and the isolation insulating layer 156 may be positioned between at least one semiconductor pattern SP and the upper surface of the substrate 110. The lower insulating layer 158 may cover one side surface of the first insulating liner 152, one side surface of the second insulating liner 154, and one side surface of the isolation insulating layer 156 in the first direction DR1. The first insulating liner 152, the second insulating liner 154, and the isolation insulating layer 156 positioned between the lowermost semiconductor pattern SP among the plurality of semiconductor patterns SP stacked in the third direction DR3 and the substrate 110.

The lower insulating layer 158 may include an insulating material. For example, the lower insulating layer 158 may include silicon oxide, silicon nitride, silicon oxynitride, or combinations thereof, but is not limited thereto.

The other end portion of the semiconductor pattern SP in the first direction DR1 may be connected to the capacitor CP. The capacitor CP may include a first electrode 171, a second electrode 175, and a dielectric layer 173 positioned between the first electrode 171 and the second electrode 175. The first electrode 171 may be connected to the other end portion of the semiconductor pattern SP in the first direction DR1. The metal silicide pattern SC may be positioned between the first electrode 171 and the semiconductor pattern SP. One side surface of the first electrode 171 in the first direction DR1 may contact the metal silicide pattern SC.

The first electrode 171 may extend in the first direction DR1. In some implementations, the first electrode 171 may have a column shape extending in the first direction DR1, but is not limited thereto. For example, the first electrode 171 may have a hollow cylindrical shape.

The dielectric layer 173 may cover the first electrode 171. The dielectric layer 173 may cover the surfaces of the first electrode 171 except for one side surface in the first direction DR1 of the first electrode 171. For example, the dielectric layer 173 may cover the other side surface of the first electrode 171 in the first direction DR1, both sides surfaces of the first electrode 171 in the second direction DR2, and both sides of the first electrode 171 in the third direction DR3.

The second electrode 175 may cover the dielectric layer 173. The second electrode 175 may be spaced apart from the first electrode 171 by the dielectric layer 173. The first electrode 171 may be surrounded by the dielectric layer 173 and the second electrode 175. The other side surface of the first electrode 171 in the first direction DR1, both side surfaces of the first electrode 171 in the second direction DR2, and both side surfaces of the first electrode 171 in the third direction DR3 may be surrounded by the dielectric layer 173 and the second electrode 175.

The semiconductor device according to some implementations may include a plurality of capacitors CP. Each of the plurality of capacitors CP may be connected to each of the plurality of semiconductor patterns SP. The first electrode 171 of each of the plurality of capacitors CP may be spaced apart from one another in the second direction DR2 and the third direction DR3. The plurality of first electrodes 171, spaced apart from one another in the second direction DR2 and the third direction DR3, may be connected to each of the plurality of semiconductor patterns SP, which are spaced apart in the second direction DR2 and the third direction DR3. The dielectric layer 173 of each of the plurality of capacitors CP, arranged along the second direction DR2 and the third direction DR3, may be interconnected. The second electrode 175 of each of the plurality of capacitors CP, arranged along the second direction DR2 and the third direction DR3, may be interconnected.

The plurality of capacitors CP may be spaced apart from one another in the first direction DR1. In some implementations, two capacitors CP adjacent in the first direction DR1 may have a symmetrical structure with reference to the bit line BL, but are not limited thereto.

The semiconductor device according to some implementations may include a plate electrode PL connected to the plurality of capacitors CP. The plate electrode PL may be connected to the plurality of capacitors CP arranged along the second direction DR2 and the third direction DR3. The plate electrode PL may cover the second electrode 175 of the plurality of capacitors CP arranged along the second direction DR2 and the third direction DR3.

In some implementations, the plate electrode PL may include a first portion PL_1 extending in the third direction DR3 perpendicular to the upper surface of the substrate 110 from one side in the first direction DR1 of first electrodes 171 of the plurality of capacitors CP, and a second portion PL_2 extending in the first direction DR1 parallel to the upper surface of the substrate 110 and positioned between the first electrodes 171.

In some implementations, the first portion PL_1 may extend in the third direction DR3 and the second direction DR2. The first portion PL_1 may have a wall shape extending in the third direction DR3 and the second direction DR2. The second portion PL_2 may surround the first electrodes 171 of the plurality of capacitors CP arranged along the second direction DR2 and the third direction DR3. However, the implementation is not limited thereto, and the structure and shape of the plate electrode PL may be variously changed corresponding to the structure and shape of the capacitor CP.

Each of the first electrode 171, second electrode 175, and plate electrode PL may include a conductive material. Each of the first electrode 171, second electrode 175, and plate electrode PL may include at least one of a metallic material such as titanium, tantalum, tungsten, copper, or aluminum; a conductive metal nitride such as titanium nitride or tantalum nitride; or a doped semiconductor material such as doped silicon or doped germanium. The first electrode 171 and the second electrode 175 may include the same material, and the plate electrode PL may include a material different from a material of the first electrode 171 and the second electrode 175. For example, the first electrode 171 and the second electrode 175 may include titanium nitride, and the plate electrode PL may include doped silicon germanium.

The dielectric layer 173 may include at least one of a dielectric, a ferroelectric, or an antiferroelectric. The dielectric may include a high permittivity material. For example, the dielectric may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof.

In some implementations, the semiconductor pattern SP, the bit line BL connected to one end portion of the semiconductor pattern SP in the first direction DR1, the capacitor CP connected to the other end portion of the semiconductor pattern SP in the first direction DR1, and the word line WL adjacent to the semiconductor pattern SP and extending in the second direction DR2 intersecting the first direction DR1 may form a memory cell MC. The semiconductor device according to some implementations may include a plurality of memory cells MC. Each of the plurality of memory cells MC may include one transistor and one capacitor connected to the transistor. For example, each of the plurality of memory cells MC may be DRAM (dynamic random access memory), but is not limited thereto. The plurality of memory cells MC may be stacked in the third direction DR3 perpendicular to the upper surface of the substrate 110. The plurality of memory cells MC may be arranged in the first direction DR1 and the second direction DR2, which are parallel to the upper surface of the substrate 110 within the same layer. That is, the semiconductor device according to some implementations may include a plurality of memory cells stacked in three dimensions.

In some implementations, the metal silicide pattern SC may be positioned between the semiconductor pattern SP and the capacitor CP. On both sides of the metal silicide pattern SC in the first direction DR1, the semiconductor pattern SP and the capacitor CP may be positioned respectively. Intermediate insulating layers ST may be positioned on both sides in the third direction DR3 and on both sides in the second direction DR2 of the metal silicide pattern SC.

In some implementations, the intermediate insulating layer ST may extend in the third direction DR3, which is perpendicular to the upper surface of the substrate 110. The intermediate insulating layer ST may further extend in the second direction DR2, which is parallel to the upper surface of the substrate 110 and intersects with a semiconductor pattern SP. The intermediate insulating layer ST may have a wall shape extending in the third direction DR3 and the second direction DR2. Through openings penetrating the intermediate insulating layer ST in the first direction DR1, the plurality of semiconductor patterns SP and the plurality of capacitors CP may be connected.

A semiconductor device according to some implementations may include a plurality of metal silicide patterns SC. The plurality of metal silicide patterns SC may connect the plurality of semiconductor patterns SP and the plurality of capacitors CP. The plurality of metal silicide patterns SC may be positioned within openings penetrating the intermediate insulating layer ST in the first direction DR1.

In some implementations, the plurality of metal silicide patterns SC may be spaced apart in the third direction DR3 and the second direction DR2 in correspondence to the plurality of semiconductor patterns SP and the plurality of capacitors CP. The plurality of metal silicide patterns SC may be spaced apart by the intermediate insulating layer ST. The intermediate insulating layer ST may be positioned between the plurality of metal silicide patterns SC that are spaced apart and arranged in the third direction DR3 and the second direction DR2. The intermediate insulating layer ST may overlap with each of the plurality of metal silicide patterns SC in the third direction DR3. The intermediate insulating layer ST may overlap with each of the plurality of metal silicide patterns SC in the second direction DR2.

In some implementations, the intermediate insulating layer ST may surround each of the plurality of metal silicide patterns SC. The intermediate insulating layer ST may be positioned on both sides in the third direction DR3 (for example, the upper and lower surfaces of the metal silicide pattern SC) and on both sides of each of the plurality of metal silicide patterns SC in the second direction DR2. The intermediate insulating layer ST may cover both sides of each of the plurality of metal silicide patterns SC in the third direction DR3 and both sides of each of the plurality of metal silicide patterns SC in the second direction DR2.

In some implementations, the width of the metal silicide pattern SC in the first direction DR1 may be smaller than the width of the intermediate insulating layer ST in the first direction DR1, but is not limited thereto. For example, the width of the metal silicide pattern SC in the first direction DR1 may be substantially the same as the width of the intermediate insulating layer ST in the first direction DR1. In another example, the width of the metal silicide pattern SC in the first direction DR1 may be greater than the width of the intermediate insulating layer ST in the first direction DR1.

In some implementations, the width of the metal silicide pattern SC in the third direction DR3 is substantially the same as the width of the semiconductor pattern SP in the third direction DR3, and the width of the metal silicide pattern SC in the second direction DR2 may be substantially the same as the width of the semiconductor pattern SP in the second direction DR2.

In some implementations, the metal silicide pattern SC may contact the intermediate insulating layer ST. Both side surfaces of the metal silicide pattern SC in the third direction DR3 (for example, the upper and lower surfaces of the metal silicide pattern SC) may contact the intermediate insulating layer ST. Both side surfaces of the metal silicide pattern SC in the second direction DR2 may contact the intermediate insulating layer ST.

In some implementations, the metal silicide pattern SC may connect the semiconductor pattern SP and the capacitor CP in the first direction DR1. One side surface of the metal silicide pattern SC in accordance with the first direction DR1 may be connected to the semiconductor pattern SP. The other side surface of the metal silicide pattern SC in accordance with the first direction DR1 may be connected to the capacitor CP.

In some implementations, the metal silicide pattern SC may contact the semiconductor pattern SP in a first direction DR1. The metal silicide pattern SC may contact the capacitor CP in the first direction DR1. One side surface of the metal silicide pattern SC in the first direction DR1 may contact the semiconductor pattern SP. The other side surface of the metal silicide pattern SC in the first direction DR1 may contact the first electrode 171 of the capacitor CP.

According to the above description, one end portion of the semiconductor pattern SP in the first direction DR1 may contact the bit line BL. The metal silicide pattern SC may contact the other end portion of the semiconductor pattern SP in the first direction DR1. In some implementations, the metal silicide pattern SC may contact the other side surface of the semiconductor pattern SP in the first direction DR1.

In some implementations, one side surface of the metal silicide pattern SC in the first direction DR1, which contacts the semiconductor pattern SP, may be aligned with one side surface of the first interlayer dielectric layer 142 in the first direction DR1 in the third direction DR3. One side surface of the metal silicide pattern SC in the first direction DR1, which contacts the semiconductor pattern SP, may be aligned with one side surface of the first interlayer dielectric layer 142 in the first direction DR1 in the second direction DR2. The metal silicide pattern SC may only contact the other side surface of the semiconductor pattern SP in the first direction DR1. Both side surfaces of the other end portion of the semiconductor pattern SP in the second direction DR2 and both side surfaces of the other end portion of the semiconductor pattern SP in the third direction DR3 may be covered by the first interlayer dielectric layer 142. The other end portion of the semiconductor pattern SP may be adjacent to the metal silicide pattern SC. The metal silicide pattern SC may contact the semiconductor pattern SP only in the first direction DR1, and may not contact in the second direction DR2 and the third direction DR3.

One side surface of the first direction DR1 of the first interlayer dielectric layer 142 may be covered by the intermediate insulating layer ST. In some implementations, one side surface of the first interlayer dielectric layer 142 in the first direction DR1 may be entirely covered by the intermediate insulating layer ST. The metal silicide pattern SC may not be positioned on one side surface of the first interlayer dielectric layer 142 in the first direction DR1. The metal silicide pattern SC may not cover one side surface of the first interlayer dielectric layer 142 in the first direction DR1.

In some implementations, as the width of the metal silicide pattern SC in the first direction DR1 is smaller than the width of the intermediate insulating layer ST in the first direction DR1, a plurality of first electrodes 171 may be further positioned within the openings of the intermediate insulating layer ST. The inner surfaces of the openings of the intermediate insulating layer ST, for example, the surfaces of the intermediate insulating layer ST facing each other in the third direction DR3 and in the second direction DR2 intermediate insulating layer may be covered by the metal silicide pattern SC and the first electrode 171.

In some implementations, the first electrode 171 may be further positioned on one side surface of the intermediate insulating layer ST in the first direction DR1. The first electrode 171 may cover a portion of one side surface of the intermediate insulating layer ST in the first direction DR1.

In some implementations, the width of the portion of the first electrode 171 adjacent to the metal silicide pattern SC may be the same as the width of the metal silicide pattern SC. The width of the portion of the first electrode 171 adjacent to the plate electrode PL may be greater than the width of the metal silicide pattern SC. Here, the width of the portion of the first electrode 171 and the width of the metal silicide pattern SC may mean the width in the third direction DR3 and the width in the second direction DR2, respectively.

In some implementations, the dielectric layer 173 of the capacitor CP may be positioned on one side surface of the intermediate insulating layer ST in the first direction DR1. The first electrode 171 and the dielectric layer 173 may be positioned on one side surface of the intermediate insulating layer ST in the first direction DR1. One side surface of the intermediate insulating layer ST in the first direction DR1 may be covered by the first electrode 171 and the dielectric layer 173.

The metal silicide pattern SC may include a metal silicide material. The work function of the metal silicide pattern SC may have a value between the work function of the material of the first electrode 171 and the work function of the material of the semiconductor pattern SP. The metal silicide pattern SC may reduce the work function difference between the material of the first electrode 171 and the material of the semiconductor pattern SP, thereby lowering the contact resistance between the semiconductor pattern SP and the capacitor CP. For example, the metal silicide pattern SC may include cobalt silicide, titanium silicide, nickel silicide, or titanium silicon nitride, but is not limited thereto.

The intermediate insulating layer ST may include an insulating material. For example, the intermediate insulating layer ST may include silicon nitride, silicon boron nitride, silicon carbon nitride, or combinations thereof, but is not limited thereto. In some implementations, the intermediate insulating layer ST may include a material different from a material of the semiconductor pattern SP. The intermediate insulating layer ST may include a material having an etch selectivity with respect to a material of the semiconductor pattern SP. For instance, the semiconductor pattern SP includes silicon, and the intermediate insulating layer ST may include silicon carbon nitride, but is not limited thereto.

FIG. 1, FIG. 2, and FIG. 5 illustrate the intermediate insulating layer ST as a single layer, but it is not limited thereto. For example, the intermediate insulating layer ST may be formed of multiple layers.

In the manufacturing process of the semiconductor device, during the step of forming the word line WL and the capacitor CP, the intermediate insulating layer ST may function as an etch stop layer. For example, when the side surface of the intermediate insulating layer ST in the first direction DR1 is exposed during the etching process, etching may be stopped. According to this, each of the plurality of word lines WL and the plurality of capacitors CP formed between the plurality of semiconductor patterns SP stacked in the third direction DR3 may be formed on a flat surface in the first direction DR1. In addition, the plurality of word lines WL and the plurality of capacitors CP may be aligned in the third direction DR3. A semiconductor device according to some implementations may include the metal silicide pattern SC positioned between the semiconductor pattern SP and the first electrode 171 connected in the first direction DR1, and the intermediate insulating layer ST overlapping in the third direction DR3, thereby improving element characteristics.

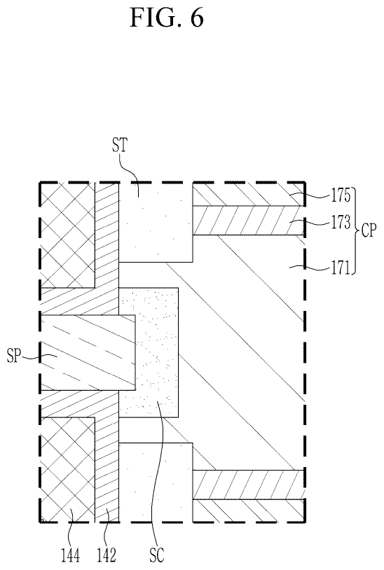

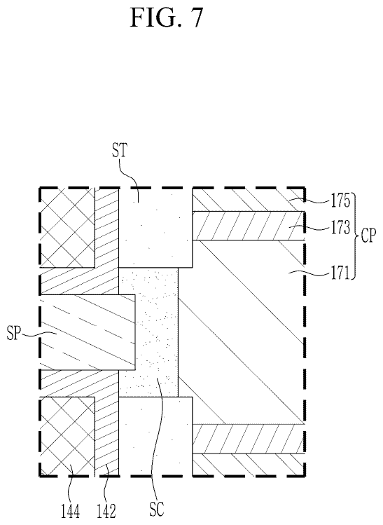

The variations of the semiconductor device according to the implementation shown in FIG. 5 will be described below with reference to FIG. 6 and FIG. 7.

FIG. 6 and FIG. 7 each represent an enlarged sectional view of a semiconductor device according to some implementations, which may be an enlarged sectional view corresponding to the P region of FIG. 2. The implementations shown in FIG. 6 and FIG. 7 have structures of the metal silicide pattern SC, the semiconductor pattern SP, the first electrode 171, and the intermediate insulating layer ST, which may differ in part from the implementations illustrated in FIG. 1 to FIG. 5. In the following, explanations overlapping prior implementations will be brief or omitted, focusing on differences.

Referring to FIG. 6 and FIG. 7, the other end portion of the semiconductor pattern SP in the first direction DR1 may be further positioned within the opening of the intermediate insulation layer ST. The semiconductor pattern SP may include a portion that overlaps with the intermediate insulation layer ST in the third direction DR3 perpendicular to the upper surface of the substrate 110. In the implementation shown in FIG. 1 to FIG. 5, the semiconductor pattern SP and the first interlayer insulation layer 142 are aligned in the third direction DR3 and the second direction DR2. On the other hand, in the implementation shown in FIG. 6 and FIG. 7, the semiconductor pattern SP and the first interlayer insulation layer 142 may not be aligned in the third direction DR3 and the second direction DR2. The semiconductor pattern SP may protrude in the first direction DR1, adjacent to the capacitor CP, more than the first interlayer insulation layer 142.

In some implementations, the metal silicide pattern SC may surround the other end portion of the semiconductor pattern SP in the first direction DR1. The metal silicide pattern SC may include a portion positioned between the semiconductor pattern SP and the intermediate insulating layer ST. In the implementation shown in FIG. 1 to FIG. 5, the metal silicide pattern SC may contact the semiconductor pattern SP only in the first direction DR1. However, in the implementations shown in FIG. 6 and FIG. 7, the metal silicide pattern SC may contact the semiconductor pattern SP in both the first direction DR1 and the third direction DR3. Although not shown, the metal silicide pattern SC may also contact the semiconductor pattern SP in the second direction DR2. The metal silicide pattern SC may cover the other side surface of the semiconductor pattern SP in the first direction DR1. The metal silicide pattern SC may cover both side surfaces in the third direction DR3, i.e., parts of the upper surface and lower surface of the semiconductor pattern SP. Although not shown, the metal silicide pattern SC may also cover parts of both side surfaces of the semiconductor pattern SP in the second direction DR2.

In some implementations, the metal silicide pattern SC may be further positioned on one side surface of the first interlayer dielectric layer 142 in the first direction DR1. In the implementation shown in FIG. 1 to FIG. 5, one side surface of the first interlayer dielectric layer 142 in the first direction DR1 may be covered only by the intermediate insulating layer ST. For example, the metal silicide pattern SC and the first interlayer dielectric layer 142 may not overlap in the first direction DR1. On the other hand, in the implementation shown in FIG. 6 and FIG. 7, one side surface of the first interlayer dielectric layer 142 in the first direction DR1 may be covered by the intermediate insulating layer ST and the metal silicide pattern SC. The metal silicide pattern SC and the first interlayer dielectric layer 142 may overlap in the first direction DR1.

Differences between the implementation shown in FIG. 6 and the implementation shown in FIG. 7 will be described below.

In the implementation shown in FIG. 6, the first electrode 171 may be positioned between the intermediate insulating layer ST and the metal silicide pattern SC. The first electrode 171 may include a portion positioned between the upper surface of the metal silicide pattern SC and the intermediate insulating layer ST and between the lower surface of the metal silicide pattern SC and the intermediate insulating layer ST. The intermediate insulating layer ST may be spaced apart from the metal silicide pattern SC by the first electrode 171. One side surface of the first interlayer dielectric layer 142 in the first direction DR1 may contact the metal silicide pattern SC, the first electrode 171, and the intermediate insulating layer ST.

In the implementation illustrated in FIG. 7, the intermediate insulating layer ST may contact the metal silicide pattern SC. One side surface of the first interlayer dielectric layer 142 along the first direction DR1 contacts the metal silicide pattern SC and the intermediate insulating layer ST, and may not contact the first electrode 171. The metal silicide pattern SC may be positioned between the first interlayer dielectric layer 142 and the first electrode 171. The first electrode 171 may be spaced apart from the first interlayer dielectric layer 142 by the metal silicide pattern SC.

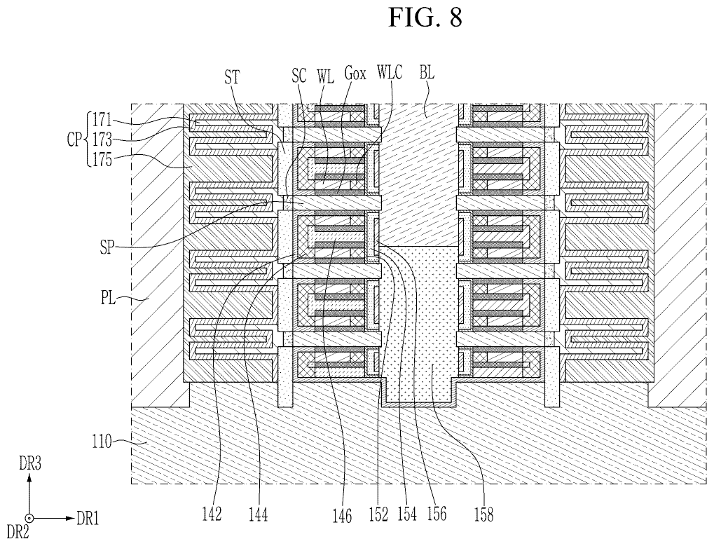

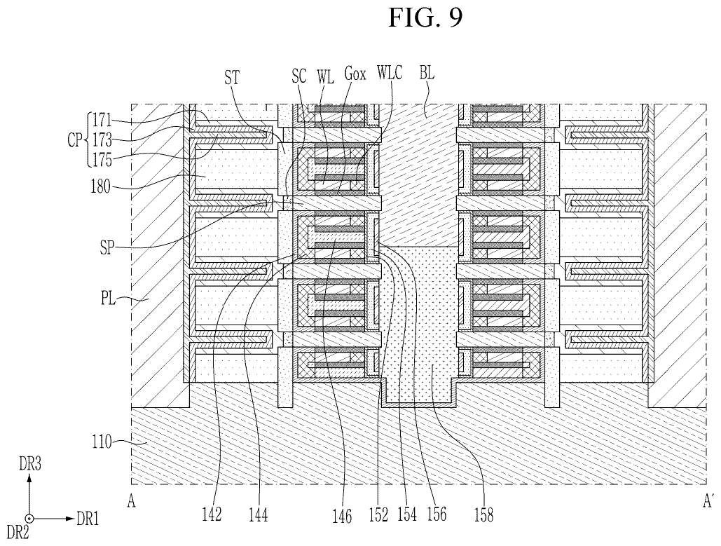

Hereinafter, with reference to FIG. 8 and FIG. 9, variations of the semiconductor device according to the implementation shown in FIG. 2 will be described.

FIG. 8 and FIG. 9 are cross-sectional views of a semiconductor device according to some implementations, which may correspond to the section shown in FIG. 2. The implementation shown in each of FIG. 8 and FIG. 9 may have the capacitor CP structure that is partially different from the implementation shown in FIG. 1 to FIG. 5. In the following, descriptions overlapping prior implementations are omitted or abbreviated, focusing on the differences.

Referring to FIG. 8 and FIG. 9, the first electrode 171 may have a shape of a hollow cylinder. The first electrode 171 may include a portion that covers one side surface of the metal silicide pattern SC and the intermediate insulating layer ST along the first direction DR1 and extends in a third direction DR3, and a portion extending in the first direction DR1 away from the semiconductor pattern SP. The dielectric layer 173 and a portion of the second electrode 175 may be positioned in the inner space surrounded by the portion of the first electrode 171 extending in the first direction DR1.

In some implementations, the plate electrode PL may extend in the third direction DR3 perpendicular to the upper surface of the substrate 110. Although not shown, the plate electrode PL may also extend in a second direction DR2. The plate electrode PL may have a wall shape extending in the second direction DR2 and the third direction DR3. The plate electrode PL may contact one side surface of the second electrode 175 in the first direction DR1.

In the implementation shown in FIG. 8 and FIG. 9, the plate electrode PL may not be positioned between the plurality of first electrodes 171 that are spaced apart in the third direction DR3. Although not shown, the plate electrode PL may also not be positioned between the plurality of first electrodes 171 that are spaced apart in the second direction DR2. For example, the plate electrode PL may only overlap with the plurality of first electrodes 171 in the first direction DR1. In the implementation shown in FIG. 8 and FIG. 9, the plate electrode PL may only contact one side surface of the second electrode 175 in accordance with the first direction DR1. The plate electrode PL may not contact both side surfaces of the second electrode 175 in accordance with the third direction DR3 and both side surfaces of the second electrode 175 in accordance with the second direction DR2.

However, the structure of the plate electrode PL is not limited to the above-described implementation. For example, as in the implementations shown in FIG. 1 to FIG. 5, a portion of the plate electrode PL may be positioned between the plurality of first electrodes 171 that are spaced apart and arranged in the third direction DR3 and the second direction DR2. For example, the plate electrode PL may overlap with the plurality of first electrodes 171 in the first direction DR1, as well as overlap in the third direction DR3 and the second direction DR2. The plate electrode PL may further contact both side surfaces of the second electrode 175 along the third direction DR3 and both side surfaces of the second electrode 175 along the second direction DR2.

In the following, differences between the implementation shown in FIG. 8 and the implementation shown in FIG. 9 will be described.

In the implementation shown in FIG. 8, the dielectric layer 173 and the second electrode 175 may cover the inner surface and the outer surface of the first electrode 171. The dielectric layer 173 and the second electrode 175 may cover one side surface of the intermediate insulating layer ST in the first direction DR1. The dielectric layer 173 may contact one side surface of the intermediate insulating layer ST in the first direction DR1. The dielectric layer 173 and the second electrode 175 may be positioned between the plurality of first electrodes 171 spaced apart in the third direction DR3.

In the implementation shown in FIG. 9, the dielectric layer 173 and the second electrode 175 may cover the inner surface of the first electrode 171. The dielectric layer 173 and the second electrode 175 do not cover the outer surface of the first electrode 171, and the dielectric layer 173 and the second electrode 175 may only cover the inner surface of the first electrode 171. The dielectric layer 173 may be spaced apart from one side surface of the intermediate insulating layer ST in the first direction DR1. A capacitor interlayer dielectric layer 180 may be positioned between the plurality of first electrodes 171 spaced apart in the third direction DR3. Unlike the implementation shown in FIG. 8, the dielectric layer 173 and the second electrode 175 may not be positioned between the plurality of first electrodes 171 spaced apart in the third direction DR3. The capacitor interlayer dielectric layer 180 may be positioned between the dielectric layer 173 and one side surface of the intermediate insulating layer ST in the first direction DR1. The dielectric layer 173 may be spaced apart from the intermediate insulating layer ST by the capacitor interlayer dielectric layer 180.

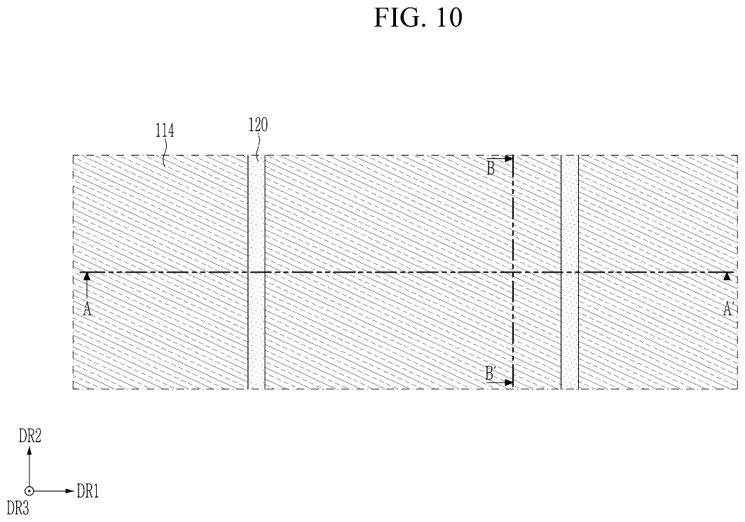

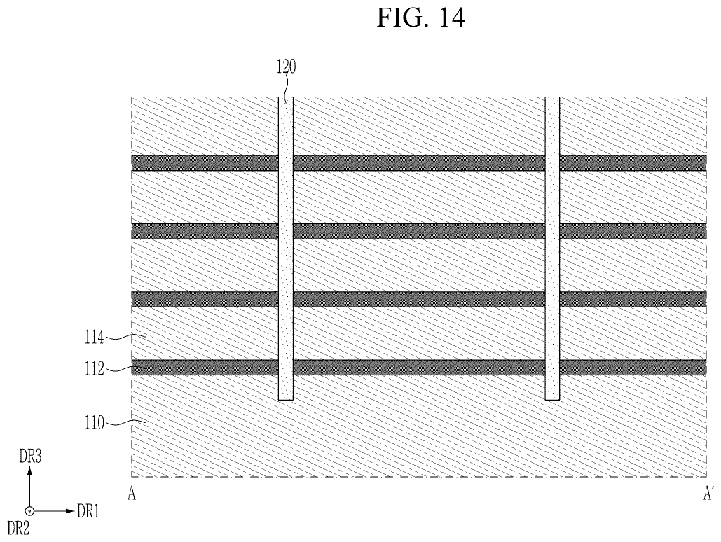

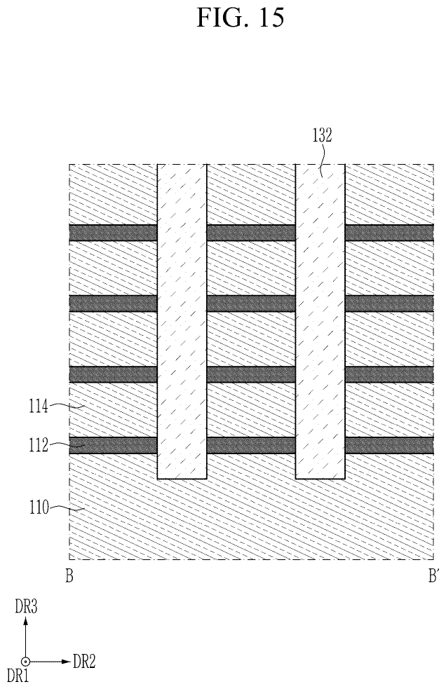

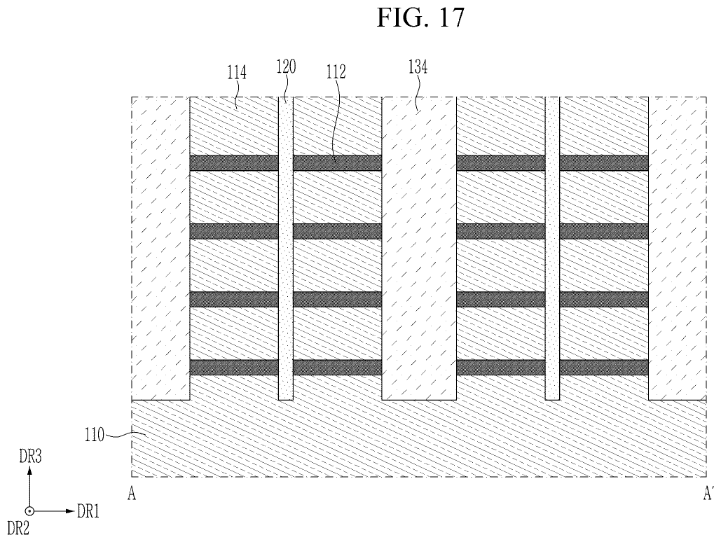

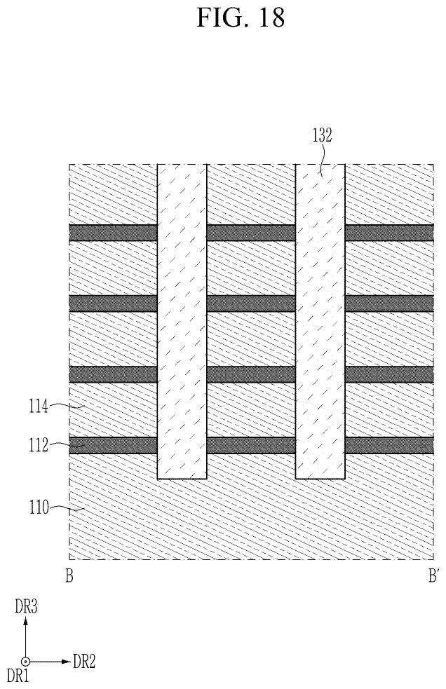

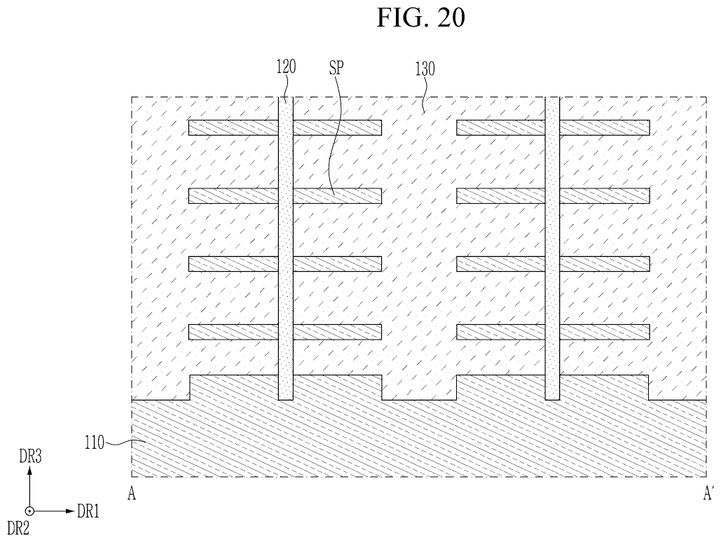

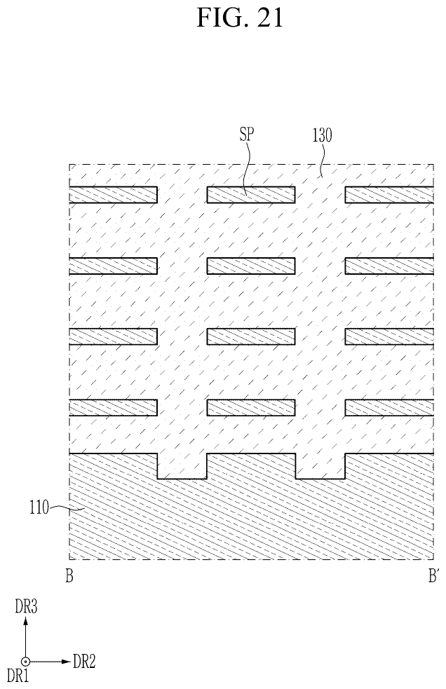

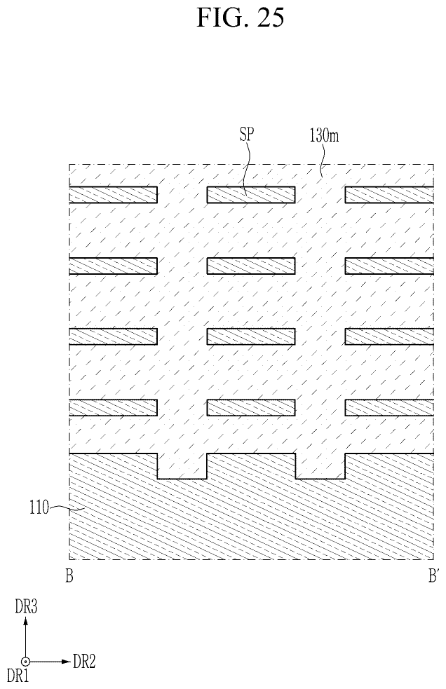

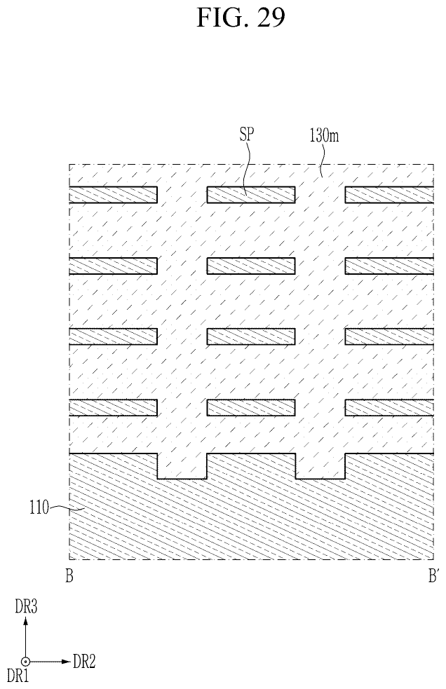

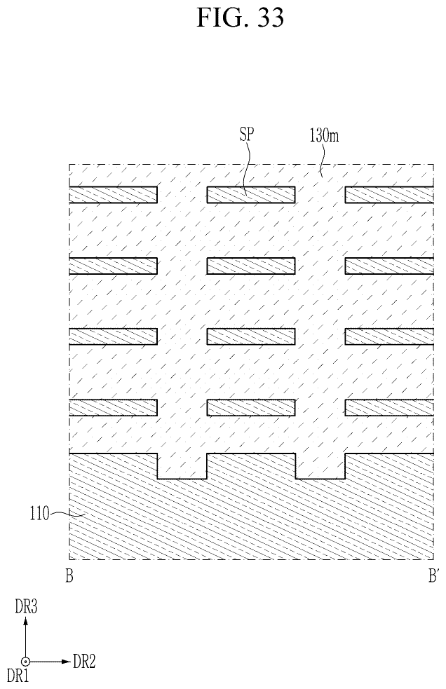

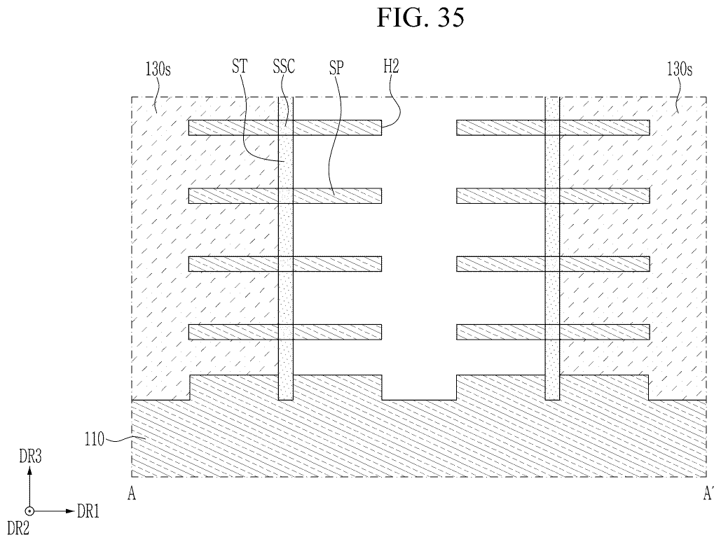

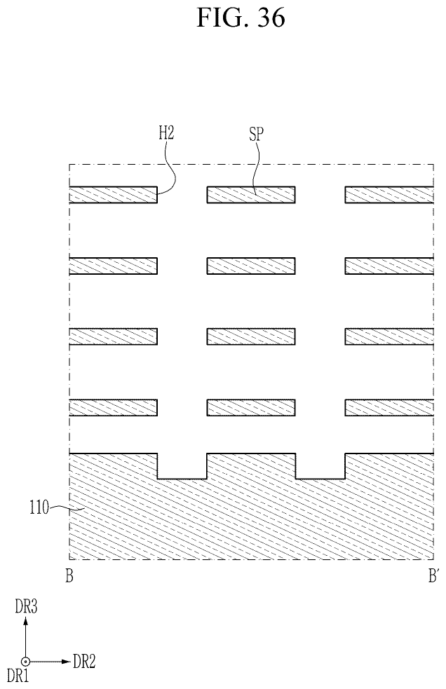

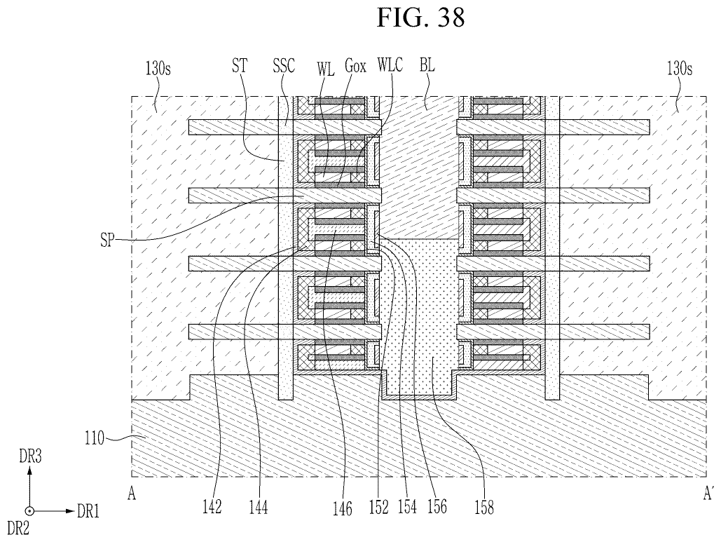

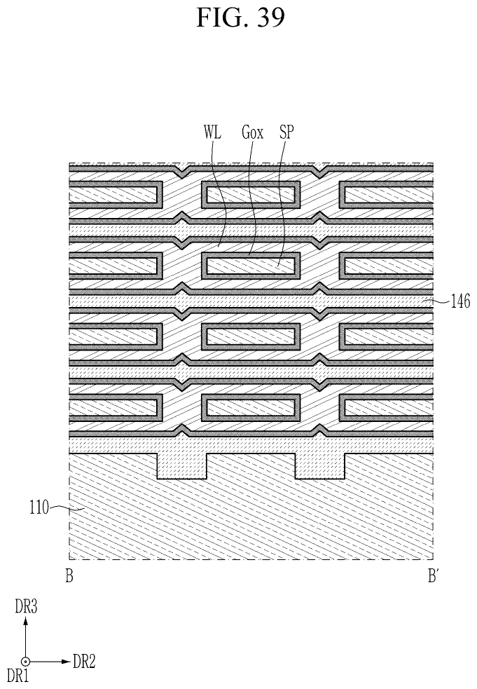

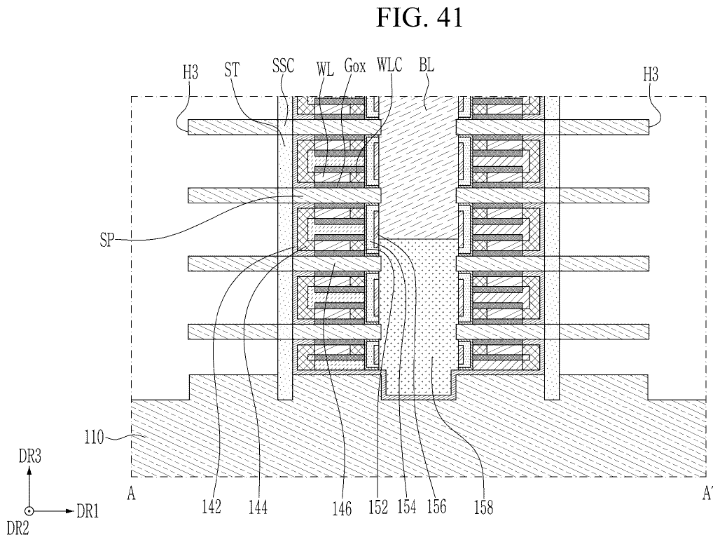

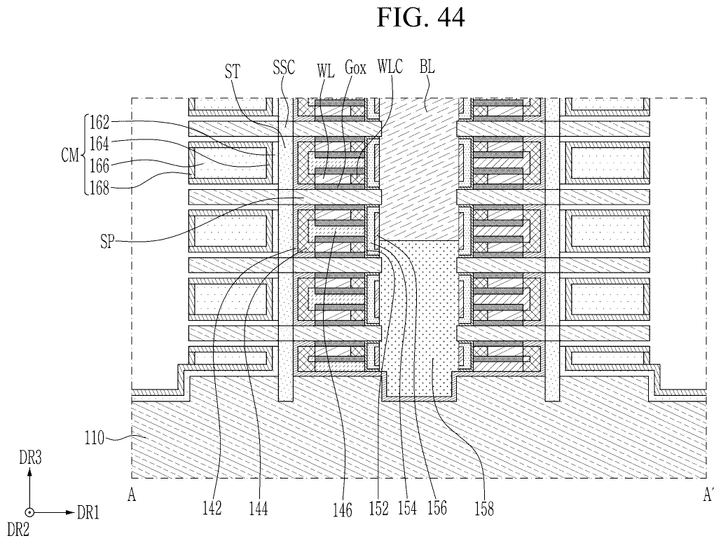

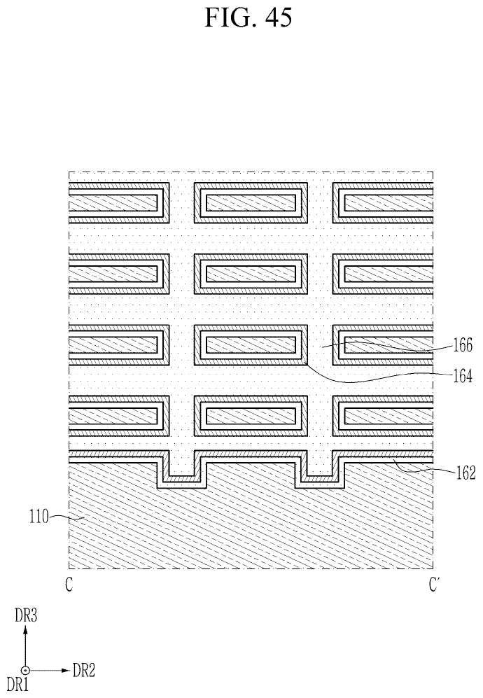

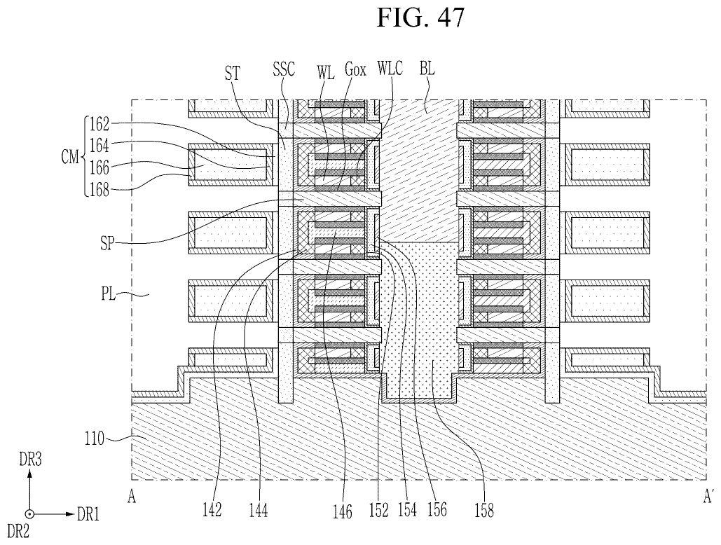

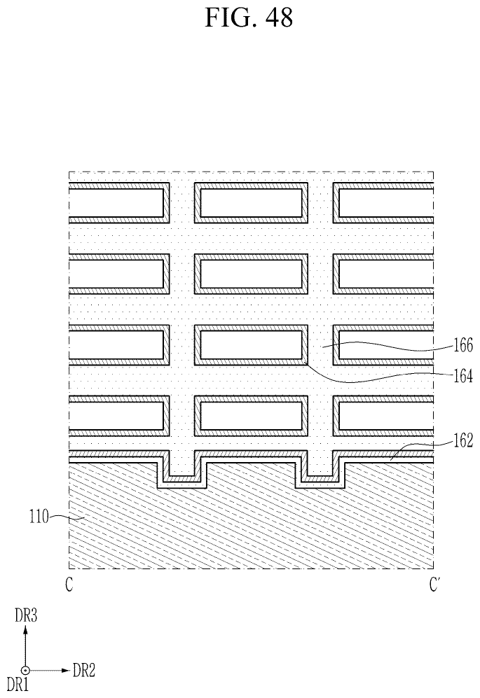

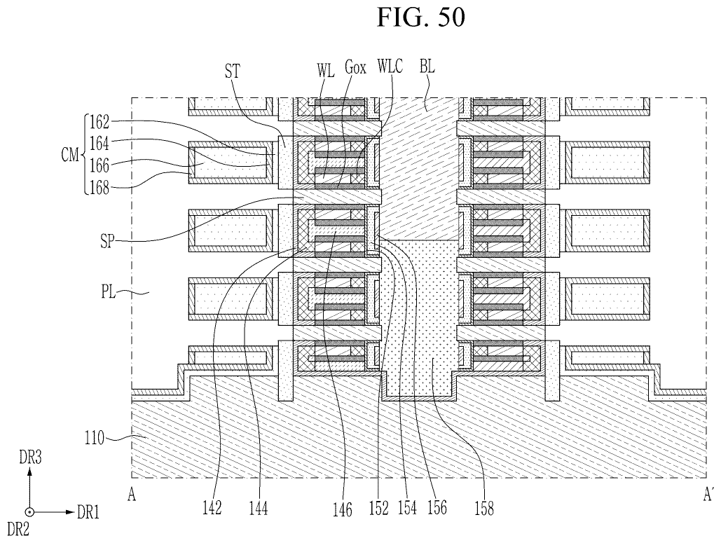

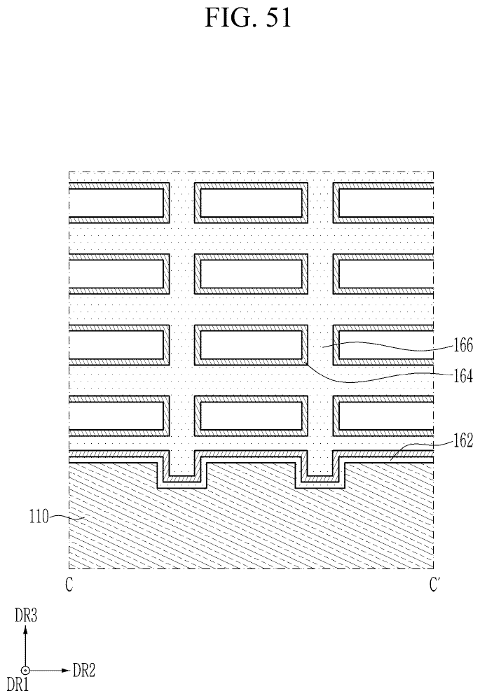

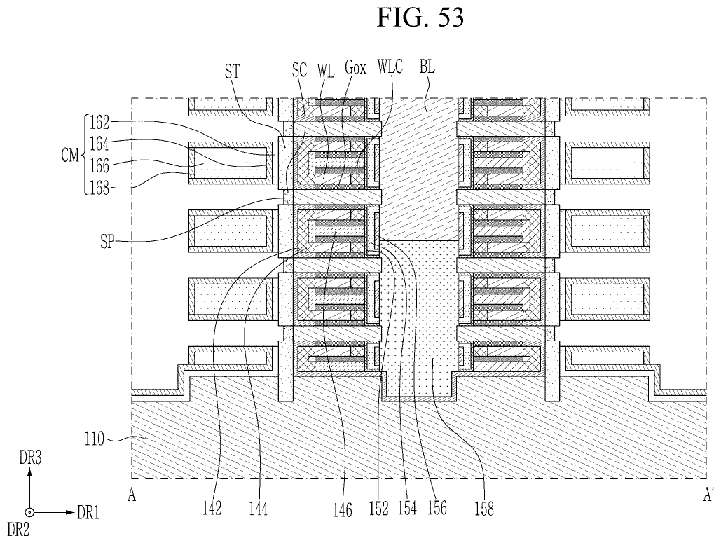

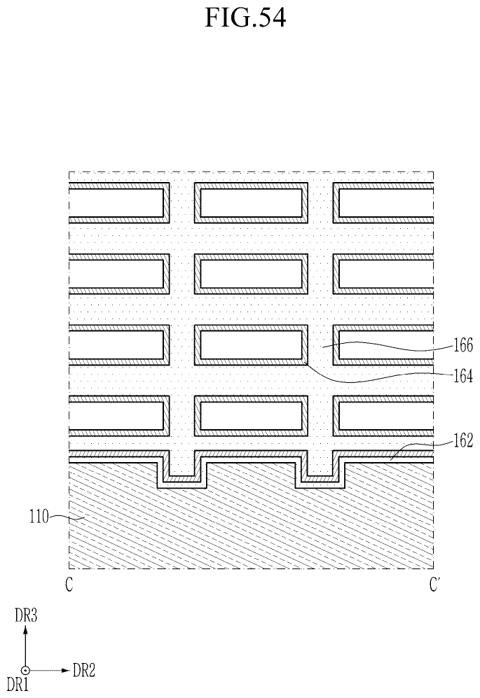

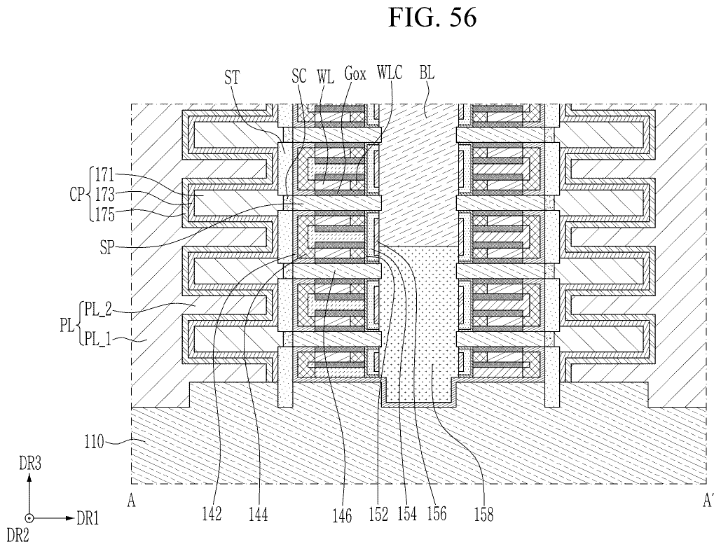

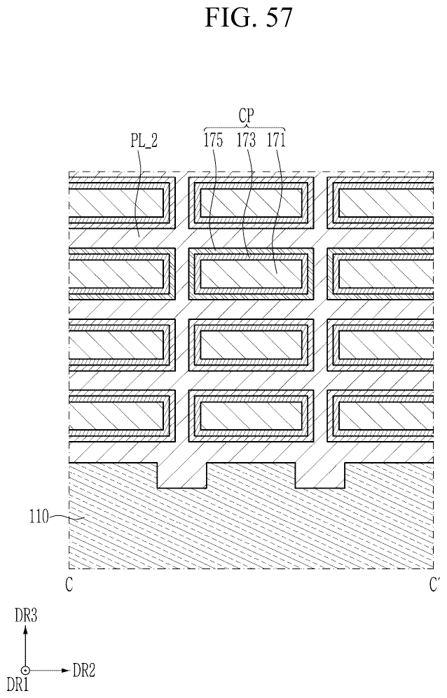

Hereinafter, with reference to FIG. 10 to FIG. 57, a method of manufacturing a semiconductor device according to some implementations will be described.

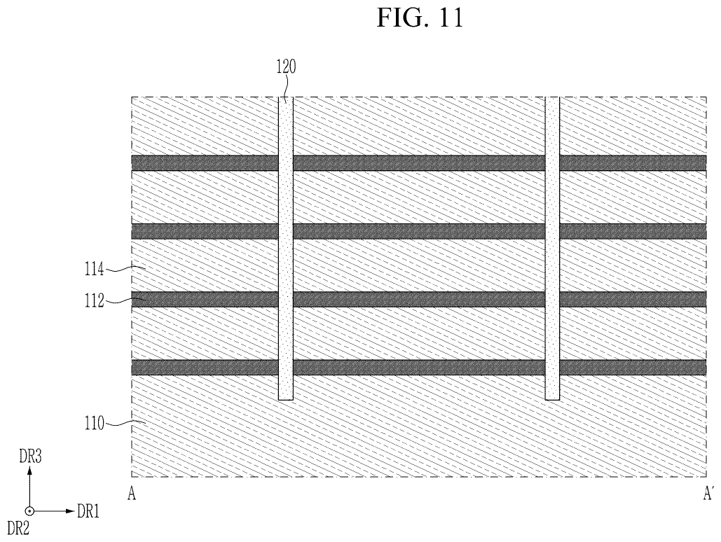

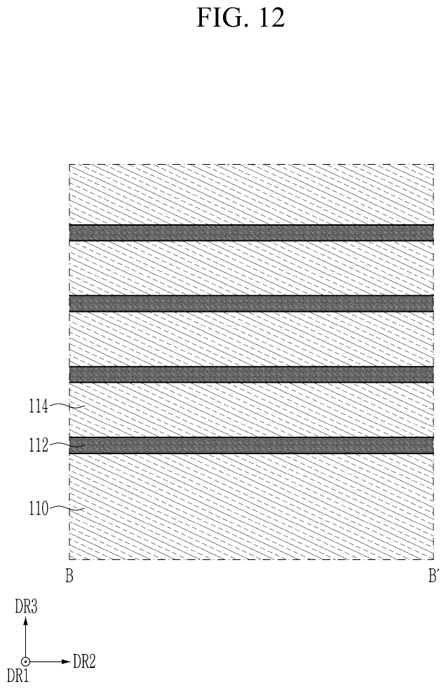

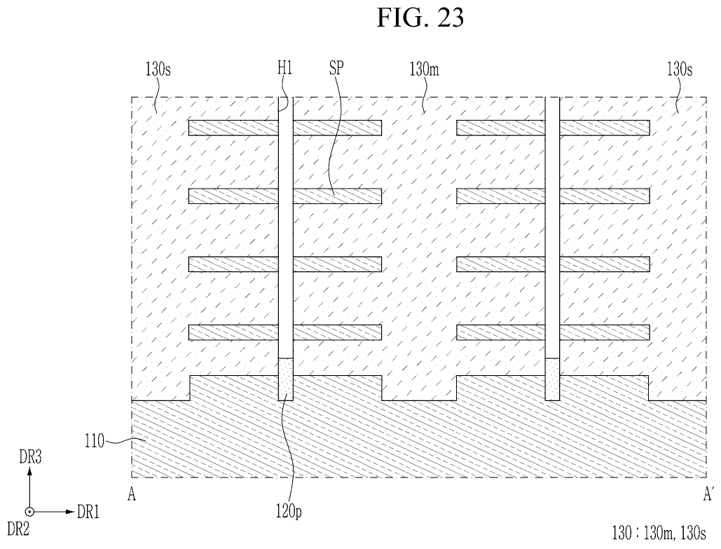

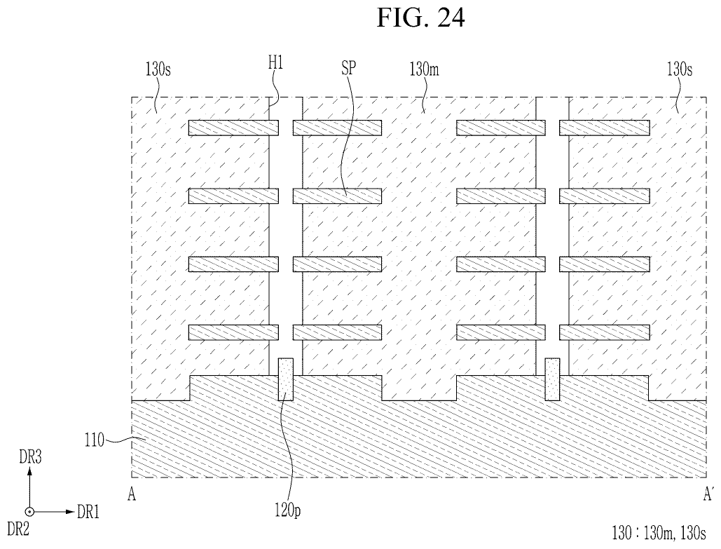

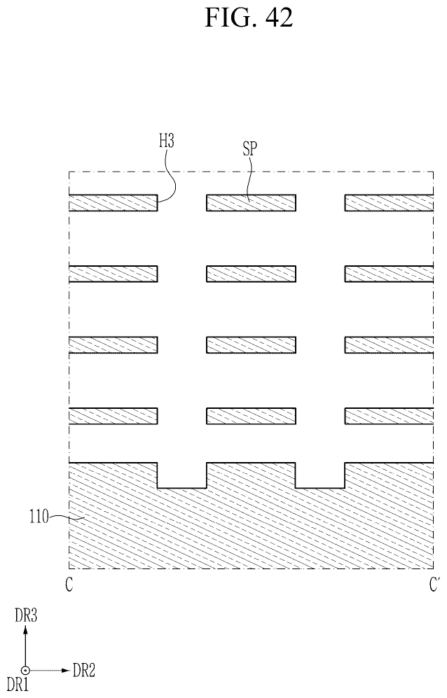

FIGS. 10 to 57 are drawings illustrating the manufacturing process of a semiconductor device according to some implementations, in order. FIGS. 10, 13, 16, 19, 22, 26, 30, 34, 37, 40, 43, 46, 49, 52, and 55 are plan views illustrating the manufacturing process of a semiconductor device according to some implementations, in order. FIGS. 11, 14, 17, 20, 23, 27, 31, 35, 38, 41, 44, 47, 50, 53, and 56 are cross-sectional views illustrating the manufacturing process of a semiconductor device according to some implementations, in order, which are cross-sectional views cut along the A-A′ line of the plan views. FIGS. 24, 28, and 32 are cross-sectional views illustrating variations of FIGS. 23, 27, and 31, respectively. FIGS. 12, 15, 18, 21, 25, 29, 33, 36, and 39 are cross-sectional views illustrating the manufacturing process of a semiconductor device according to some implementations, in order, which are cross-sectional views cut along the B-B′ line of the plan views. FIGS. 42, 45, 48, 51, 54, and 57 are cross-sectional views illustrating the manufacturing process of a semiconductor device according to some implementations, in order, which are cross-sectional views cut along the C-C′ line of the plan views.

Referring to FIG. 10 to FIG. 12, a plurality of first semiconductor layers 112 and a plurality of second semiconductor layers 114 are formed on the substrate 110, and a preliminary intermediate insulating layer 120 penetrating the plurality of first semiconductor layers 112 and the plurality of second semiconductor layers 114 may be formed.

First, a plurality of first semiconductor layers 112 and a plurality of second semiconductor layers 114 may be alternately formed on the substrate 110. For example, the plurality of first semiconductor layers 112 and the plurality of second semiconductor layers 114 may be formed through a deposition process. For example, the plurality of first semiconductor layers 112 and the plurality of second semiconductor layers 114 may be formed by chemical vapor deposition (CVD), physical vapor deposition (PVD), or atomic layer deposition (ALD), but are not limited thereto. As another example, the plurality of first semiconductor layers 112 and the plurality of second semiconductor layers 114 may also be formed through the epitaxial growth method.

The first semiconductor layer 112 and the second semiconductor layer 114 each may include a semiconductor material. The first semiconductor layer 112 and the second semiconductor layer 114 may include different semiconductor materials. The second semiconductor layer 114 may include a material having an etch selectivity with respect to a material of the first semiconductor layer 112. In some implementations, the first semiconductor layer 112 includes SiGe, and the second semiconductor layer 114 may include Si, but is not limited thereto.

In some implementations, the second semiconductor layer 114 may be formed thicker than the first semiconductor layer 112, but is not limited thereto. For instance, the second semiconductor layer 114 may also be formed thinner than the first semiconductor layer 112. In this case, the thinning process of the second semiconductor layer 114 in subsequent processes may be omitted.

Subsequently, a preliminary intermediate insulating layer 120 may be formed penetrating through the plurality of first semiconductor layers 112 and the plurality of second semiconductor layers 114. The preliminary intermediate insulating layer 120 may penetrate through the plurality of first semiconductor layers 112 and the plurality of second semiconductor layers 114 in a third direction DR3, which is perpendicular to the upper surface of the substrate 110, and be connected to the substrate 110. A portion of the preliminary intermediate insulating layer 120 may be embedded in the upper portion of the substrate 110. The lower portion of the preliminary intermediate insulating layer 120 may be surrounded by the substrate 110. Some portions of the lower surface and side surfaces of the preliminary intermediate insulating layer 120 may be covered by the substrate 110.

The preliminary intermediate insulating layer 120 may extend in the third direction DR3 and the second direction DR2. The preliminary intermediate insulating layer 120 may have a wall shape extending in the third direction DR3 and the second direction DR2.

In some implementations, a plurality of preliminary intermediate insulating layers 120 may be formed spaced apart in a first direction DR1.

The preliminary intermediate insulating layer 120 may include an insulating material. The preliminary intermediate insulating layer 120 may include an insulating material that has an etch selectivity with respect to a material of the first semiconductor layer 112 and a material of the second semiconductor layer 114. For example, the preliminary intermediate insulating layer 120 may include silicon nitride, silicon boron nitride, silicon carbonitride, or combinations thereof, but is not limited thereto.

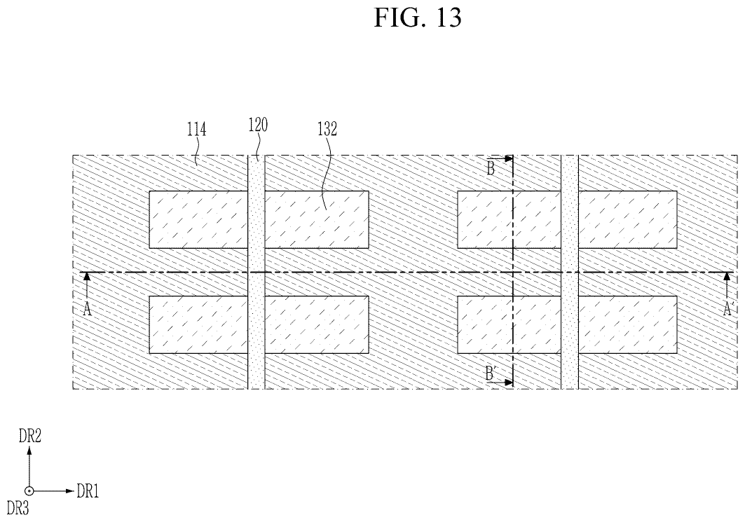

Referring to FIGS. 13 to 15, a plurality of first cell isolation insulating layers 132 may be formed on both side surfaces of the preliminary intermediate insulating layer 120 in the first direction DR1.

First, a plurality of first cell isolation holes may be formed penetrating the plurality of first semiconductor layers 112 and the plurality of second semiconductor layers 114. Each of the plurality of first cell isolation holes may recess a portion of the upper surface of the substrate 110. The bottom surface of each of the plurality of first cell isolation holes may be formed from the upper surface of the substrate 110. The sidewalls of each of the plurality of first cell isolation holes may be formed from a portion of the side surfaces of the substrate 110, the side surfaces of the plurality of first semiconductor layers 112, and the side surfaces of the plurality of second semiconductor layers 114.

Subsequently, the plurality of first cell isolation holes may be filled with an insulating material to form a plurality of first cell isolation insulating layers 132. The first cell isolation insulating layers 132 may include, for example, silicon oxide, but are not limited thereto. The first cell isolation insulating layers 132 may penetrate the plurality of first semiconductor layers 112 and the plurality of second semiconductor layers 114 and be connected to the substrate 110. The first cell isolation insulating layers 132 may cover the upper surface of the substrate 110 and partially cover the side surfaces of the substrate 110. The first cell isolation insulating layers 132 may cover the side surfaces of the plurality of first semiconductor layers 112 facing in the first direction DR1 and the side surfaces of the plurality of second semiconductor layers 114 facing in the first direction DR1.

The plurality of first cell isolation insulating layers 132 may be positioned on both sides in the first direction DR1 with reference to the preliminary intermediate insulating layer 120. The plurality of first cell isolation insulating layers 132 may be spaced apart and arranged in the second direction DR2. Two first cell isolation insulating layers 132 may be spaced apart and arranged in the first direction DR1 between adjacent preliminary intermediate insulating layers 120.

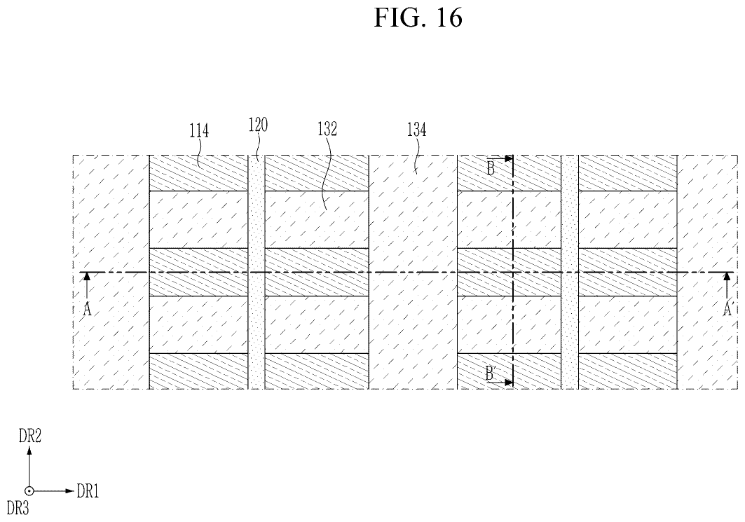

Referring to FIG. 16 to FIG. 18, a second cell isolation insulating layer 134 may be formed on the side surfaces of the plurality of first cell isolation insulating layers 132 in the first direction DR1. The plurality of first cell isolation insulating layers may be spaced apart and arranged in the second direction DR2. In some implementations, the plurality of second cell isolation insulating layers 134 may be formed to be spaced apart in the first direction DR1.

First, a plurality of second cell isolation holes may be formed, penetrating through the plurality of first semiconductor layers 112 and the plurality of second semiconductor layers 114. Each of the plurality of second cell isolation holes may partially recess the upper surface of the substrate 110. The bottom surfaces of each of the plurality of second cell isolation holes may be formed by the upper surface of the substrate 110. The sidewalls of each of the plurality of second cell isolation holes may be formed by portions of the side surfaces of the substrate 110, the side surfaces of the plurality of first semiconductor layers 112, the side surfaces of the plurality of second semiconductor layers 114, and the side surfaces of the plurality of first cell isolation insulating layers 132.

Subsequently, an insulating material may be filled into the plurality of second cell isolation holes to form a plurality of second cell isolation insulating layers 134. In some implementations, the second cell isolation insulating layer 134 may include the same material as a material of the first cell isolation insulating layer 132, but it is not limited thereto. For example, the second cell isolation insulating layer 134 may include silicon oxide, but it is not limited thereto. The second cell isolation insulating layer 134 may penetrate through the plurality of first semiconductor layers 112 and the plurality of second semiconductor layers 114 and connect to the substrate 110. The second cell isolation insulating layer 134 may cover the upper surface of the substrate 110 and a portion of the side surfaces of the substrate 110. The second cell isolation insulating layer 134 may cover the facing side surfaces of the plurality of first semiconductor layers 112 and the facing side surfaces of the plurality of second semiconductor layers 114 in the first direction DR1. The second cell isolation insulating layer 134 may cover the one side surface of the plurality of first cell isolation insulating layers 132 in the first direction DR1. The plurality of first cell isolation insulating layer 132 may be arranged spaced apart in the second direction DR2.

The second cell isolation insulating layer 134 may be positioned between two first cell isolation insulating layers 132, which are positioned between adjacent preliminary intermediate insulating layers 120. The second cell isolation insulating layer 134 may cover the side surfaces of the two first cell isolation insulating layers 132 facing in the first direction DR1. The two first cell isolation insulating layers 132 may be positioned between adjacent preliminary intermediate insulating layers 120.

The plurality of first semiconductor layers 112 and the plurality of second semiconductor layers 114 may be separated in the second direction DR2 by the plurality of first cell isolation insulating layers 132. The plurality of first semiconductor layers 112 and the plurality of second semiconductor layers 114 may be separated in the first direction DR1 by the plurality of second cell isolation insulating layers 134.

In the implementations shown in FIG. 10 to FIG. 18, the preliminary intermediate insulating layer 120 is first formed, and then the first cell isolation insulating layer 132 is formed, followed by the formation of the second cell isolation insulating layer 134. However, the implementations are not limited to this. For example, the first cell isolation insulating layer 132 may be formed first, followed by the formation of the preliminary intermediate insulating layer 120, and then the second cell isolation insulating layer 134. In another example, the first cell isolation insulating layer 132 may be formed first, followed by the second cell isolation insulating layer 134, and then the preliminary intermediate insulating layer 120.

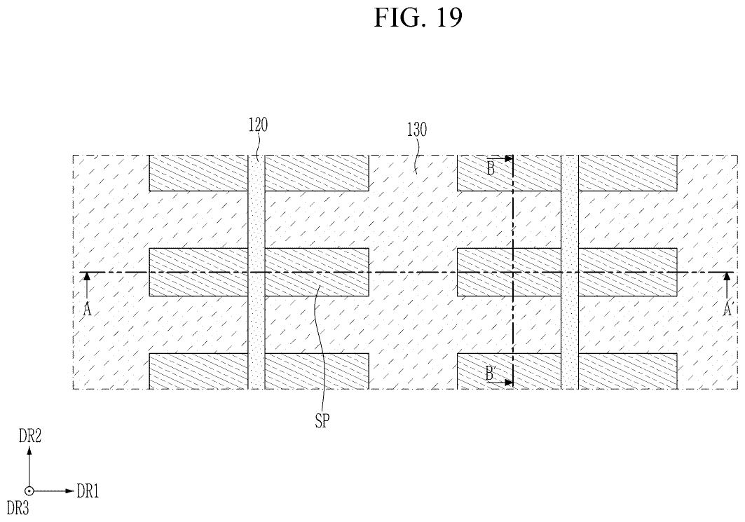

Referring to FIG. 19 to FIG. 21, the plurality of first semiconductor layers 112 may be removed, and the plurality of second semiconductor layers 114 may be thinned to form the plurality of semiconductor patterns SP, and a cell isolation insulating layer 130 may be formed.

First, portions of the plurality of first cell isolation insulating layers 132 and the plurality of second cell isolation insulating layers 134 may be etched to expose the side surfaces of the plurality of first semiconductor layers 112 and the side surfaces of the plurality of second semiconductor layers 114. The remaining portions of the plurality of first cell isolation insulating layers 132 and the plurality of second cell isolation insulating layers 134 that are not etched may support the structure of the plurality of second semiconductor layers 114 during subsequent processes. Subsequently, the plurality of first semiconductor layers 112 among the plurality of first semiconductor layers 112 and the plurality of second semiconductor layers 114 may be selectively etched using a material with a high etch selectivity to the first semiconductor layers 112 relative to the second semiconductor layers 114. Through the etching process, the plurality of first semiconductor layers 112 may be removed.

Subsequently, a thinning process may be performed on the plurality of second semiconductor layers 114 to form the plurality of semiconductor patterns SP. Through the thinning process, the thickness of each of the plurality of second semiconductor layers 114 may be reduced. Here, the thickness of the second semiconductor layer 114 may refer to the length in the third direction DR3. That is, the thickness of the plurality of semiconductor patterns SP may be thinner than the thickness of the plurality of second semiconductor layers 114.

The plurality of semiconductor patterns SP may be spaced apart and stacked in the third direction DR3 perpendicular to the upper surface of the substrate 110. The plurality of semiconductor patterns SP may be spaced apart and arranged in the second direction DR2 parallel to the upper surface of the substrate 110. The plurality of semiconductor patterns SP may be spaced apart and arranged in the first direction DR1 that is parallel to the upper surface of the substrate 110 and intersects the second direction DR2. The plurality of semiconductor patterns SP may be positioned on both side surfaces of a preliminary intermediate insulating layer 120 along the first direction DR1. The plurality of semiconductor patterns SP may be spaced apart and arranged in the first direction DR1 between adjacent preliminary intermediate insulating layers 120.

Subsequently, a cell isolation insulating layer 130 may be formed to surround the plurality of semiconductor patterns SP. The cell isolation insulating layer 130 may include remaining portions that are not etched of the plurality of first cell isolation insulating layers 132 and the plurality of second cell isolation insulating layers 134, but is not limited thereto. For example, the cell isolation insulating layer 130 may be newly formed after the plurality of first cell isolation insulating layers 132 and the plurality of second cell isolation insulating layers 134 are completely removed. In some implementations, the cell isolation insulating layer 130 may include a plurality of isolation insulating layers formed with sections divided such as the plurality of first cell isolation insulating layers 132 and the plurality of second cell isolation insulating layers 134. In this case, as the plurality of isolation insulating layers include the same insulating material, boundaries between the plurality of isolation insulating layers may not be identifiable. The cell isolation insulating layer 130 may include, for example, silicon oxide, but is not limited thereto.

The cell isolation insulating layer 130 may cover one side surface of each of the plurality of semiconductor patterns SP in the first direction DR1, both side surfaces of each of the plurality of semiconductor patterns SP in the second direction DR2, and both side surfaces of each of the plurality of semiconductor patterns SP in the third direction DR3. The other side surface of each of the plurality of semiconductor patterns SP in the first direction DR1 may be covered by the preliminary intermediate insulating layer 120.

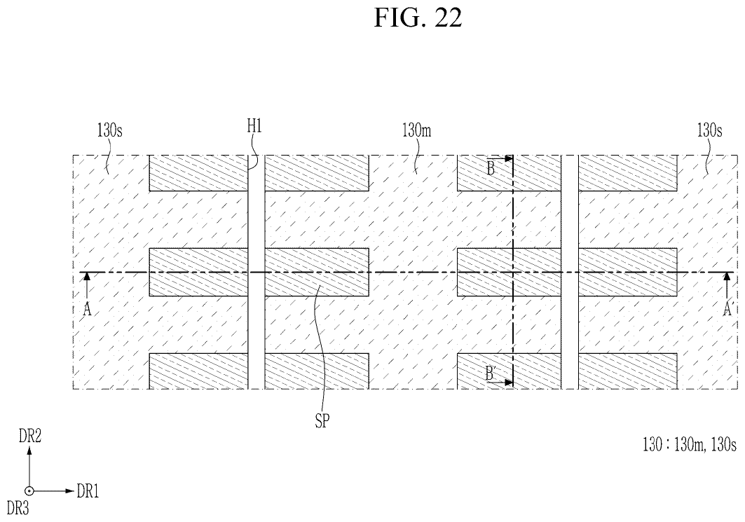

Referring to FIG. 22 through FIG. 25, a portion of the preliminary intermediate insulating layer 120 may be etched to form a first hole H1. For example, using a material with a high etch selectivity for the preliminary intermediate insulating layer 120 relative to the semiconductor pattern SP and the cell isolation insulating layer 130, the preliminary intermediate insulating layer 120 may be selectively etched. The upper portion of the preliminary intermediate insulating layer 120 is etched, and the lower portion adjacent to the upper surface of the substrate 110 of the preliminary intermediate insulating layer 120 may remain, which may be referred to as the remaining intermediate insulating layer 120p. The remaining intermediate insulating layer 120p may cover a portion of the upper surface and side surfaces of the substrate 110, and a portion of the side surfaces of the cell isolation insulating layer 130 adjacent to the upper surface of the substrate 110.

The bottom surface of the first hole H1 may be formed by the upper surface of the remaining intermediate insulating layer 120p. The sidewalls of the first hole H1 may be formed by the side surfaces of the plurality of semiconductor patterns SP and the side surface of a cell isolation insulating layer 130. Through the first hole H1, the side surfaces of the plurality of semiconductor patterns SP and the side surface of the cell isolation insulating layer 130 may be exposed. The side surfaces of the plurality of semiconductor patterns SP exposed through the first hole H1 may be side surfaces in accordance with the first direction DR1. The two semiconductor patterns SP positioned on both sides of the first hole H1 may face each other in the first direction DR1.

In some implementations, a plurality of first holes H1 may be formed to be spaced apart in the first direction DR1. Each of the plurality of first holes H1 may extend in the third direction DR3 and the second direction DR2, and each of the plurality of first holes H1 may have a wall shape extending in the third direction DR3 and the second direction DR2. A portion of the cell isolation insulating layer 130 positioned between adjacent first holes H1 may be referred to as a intermediate cell isolation insulating layer 130m. A portion of the cell isolation insulating layer 130 positioned on the other side surface of the intermediate cell isolation insulating layer 130mbased on the first hole H1 may be referred to as a side cell isolation insulating layer 130s. The intermediate cell isolation insulating layer 130m and the side cell isolation insulating layer 130s positioned on both sides of the first hole H1 may face each other in the first direction DR1.

In the implementation shown in FIG. 24, unlike the implementation shown in FIG. 23, after etching a portion of the preliminary intermediate insulating layer 120, a portion of the cell isolation insulating layer 130 may be etched. As a result, portions of both side surfaces of the plurality of semiconductor patterns SP in the third direction DR3 and portions of the upper surface of the substrate 110 may be further exposed. Although not shown, both side surfaces of the plurality of semiconductor patterns SP in the second direction DR2 may also be exposed.

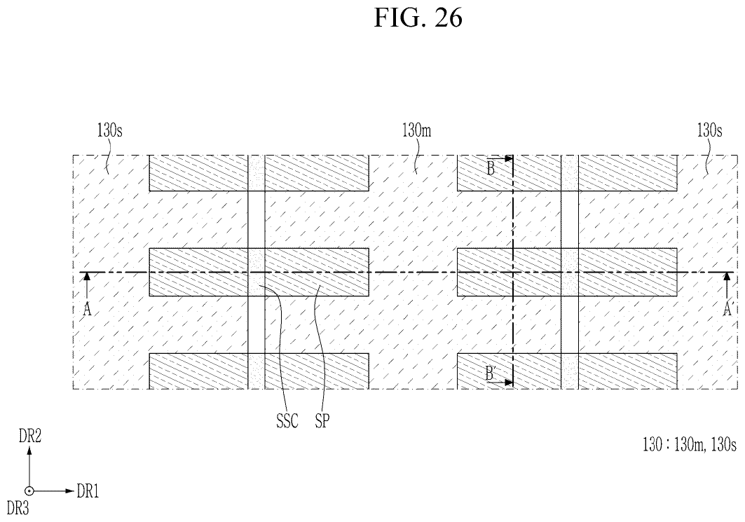

Referring to FIG. 26 to FIG. 29, a sacrificial metal silicide pattern SSC may be formed on the side surfaces of the plurality of semiconductor patterns SP in a first direction DR1. The sacrificial metal silicide pattern SSC may be formed, for example, through an area selective deposition (ASD) process. The sacrificial metal silicide pattern SSC is formed only on the surfaces of the semiconductor patterns SP, and not on the surfaces of the cell isolation insulating layer 130 and the remaining intermediate insulating layer 120p.

The sacrificial metal silicide pattern SSC may cover the facing sides of the two semiconductor patterns SP positioned on both sides of the first hole H1 in the first direction DR1. The sacrificial metal silicide pattern SSC may connect between the two semiconductor patterns SP positioned on both sides of the first hole H1.

In some implementations, a plurality of sacrificial metal silicide patterns SSC may be formed corresponding to the plurality of semiconductor patterns SP. The plurality of sacrificial metal silicide patterns SSC may be formed to be spaced apart in the second direction DR2 and the third direction DR3 within the first hole H1. The plurality of sacrificial metal silicide patterns SSC positioned within the respective adjacent first holes H1 may be spaced apart from each other in a first direction DR1.

The sacrificial metal silicide pattern SSC may include a metal silicide material. For example, the sacrificial metal silicide pattern SSC may include cobalt silicide, titanium silicide, nickel silicide, or titanium silicon nitride, but is not limited thereto.

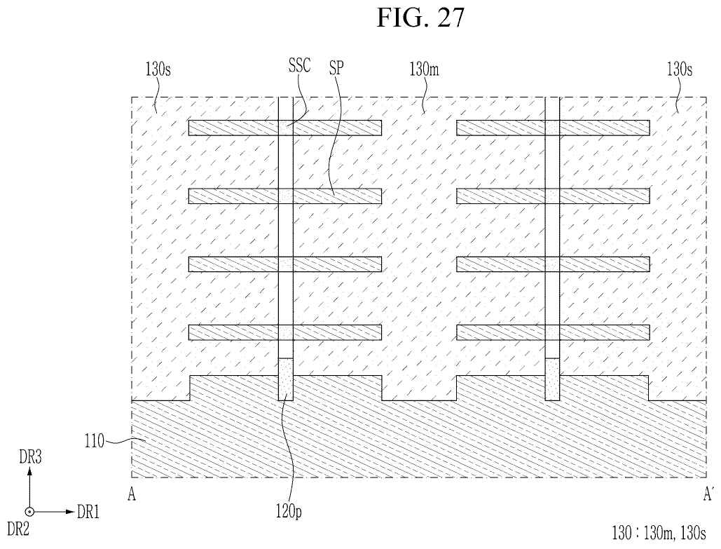

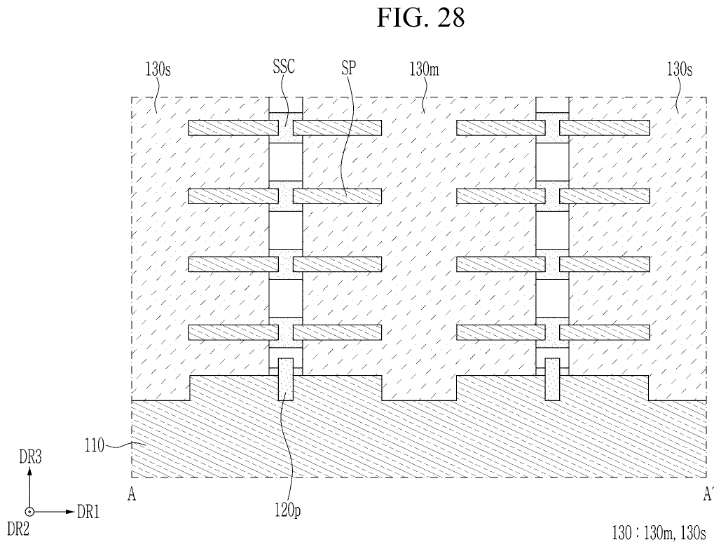

In the implementation shown in FIG. 28, unlike the implementation shown in FIG. 27, the sacrificial metal silicide pattern SSC may further cover portions of both side surfaces of the plurality of semiconductor patterns SP in the third direction DR3 and a portion of the upper surface of the substrate 110. Although not shown, the sacrificial metal silicide pattern SSC may also cover portions of both side surfaces of the plurality of semiconductor patterns SP in the second direction DR2.

As shown in FIG. 24 and FIG. 28, as a portion of the cell isolation insulating layer 130 is further etched, the sacrificial metal silicide pattern SSC of the implementation shown in FIG. 28 may be formed thicker than the sacrificial metal silicide pattern SSC of the implementation shown in FIG. 27. Here, the thickness may refer to the maximum width in the first direction DR1, the second direction DR2, and the third direction DR3. In this case, even if the sacrificial metal silicide pattern SSC becomes thinner due to partial loss in a subsequent process, it may still cover one side surface of the semiconductor pattern SP in the first direction DR1. As the sacrificial metal silicide pattern SSC covers one side surface of the semiconductor pattern SP in the first direction DR1, it is possible to selectively remove the sacrificial metal silicide pattern SSC later and accurately expose only the region of the semiconductor pattern SP that contacts the capacitor CP, thereby preventing bridge defects between adjacent capacitors CP. Meanwhile, as the processes described later are performed on the implementation shown in FIG. 28, the semiconductor device according to the implementation shown in FIG. 6 or FIG. 7 may be formed.

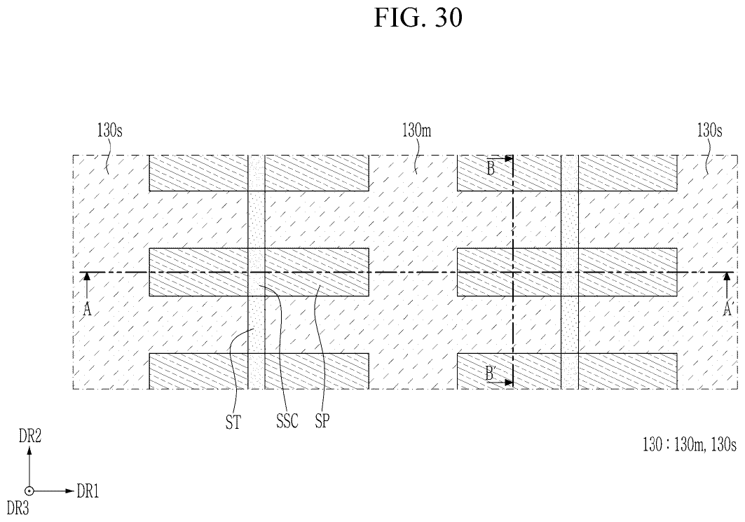

Referring to FIG. 30 to FIG. 33, an intermediate insulating layer ST may be formed. An intermediate insulating layer ST may be formed by filling insulating material in the first hole H1. The intermediate insulating layer ST may include insulating material. The intermediate insulating layer ST may include material different from a material of the cell isolation insulating layer 130 and a material of the semiconductor pattern SP. The intermediate insulating layer ST may include insulating material having an etch selectivity relative to a material of the cell isolation insulating layer 130 and a material of the semiconductor pattern SP. For example, the cell isolation insulating layer 130 may include silicon oxide, and the semiconductor pattern SP may include silicon. For instance, the intermediate insulating layer ST may include silicon nitride, silicon boron nitride, silicon carbonitride, or combinations thereof, but is not limited thereto.

The intermediate insulating layer ST may include the same material as a material of the preliminary intermediate insulating layer 120 and a material of the remaining intermediate insulating layer 120p. Accordingly, the interface between the intermediate insulating layer ST and the remaining intermediate insulating layer 120p may not be identifiable.

The intermediate insulating layer ST may be positioned on both sides of the sacrificial metal silicide pattern SSC in the third direction DR3. The intermediate insulating layer ST may be positioned on both sides of the sacrificial metal silicide pattern SSC in the second direction DR2. The intermediate insulating layer ST may surround the sacrificial metal silicide pattern SSC in the second direction DR2 and the third direction DR3.

The intermediate insulating layer ST may overlap with the sacrificial metal silicide pattern SSC in the third direction DR3. The intermediate insulating layer ST may cover both side surfaces of the sacrificial metal silicide pattern SSC along the third direction DR3. The intermediate insulating layer ST may contact the both side surfaces of the sacrificial metal silicide pattern SSC along the third direction DR3.

The intermediate insulating layer ST may overlap with the sacrificial metal silicide pattern SSC in the second direction DR2. The intermediate insulating layer ST may cover the side surfaces of the sacrificial metal silicide pattern SSC in the second direction DR2. The intermediate insulating layer ST may contact the side surfaces of the sacrificial metal silicide pattern SSC in the second direction DR2.

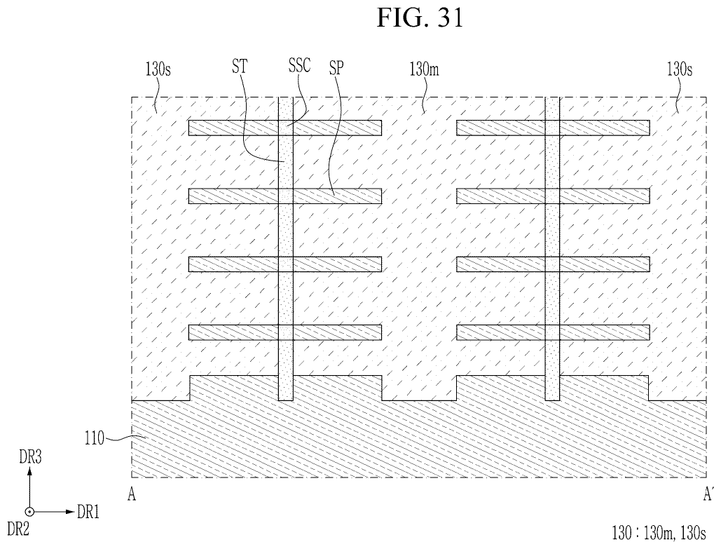

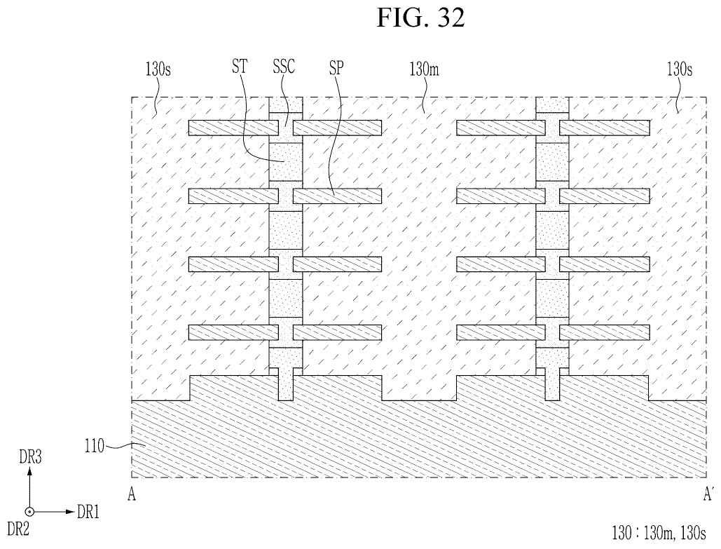

In the implementation shown in FIG. 32, unlike the implementation shown in FIG. 31, the sacrificial metal silicide pattern SSC may overlap with the semiconductor pattern SP in the third direction DR3. Although not illustrated, the sacrificial metal silicide pattern SSC may also overlap with the semiconductor pattern SP in the second direction DR2.

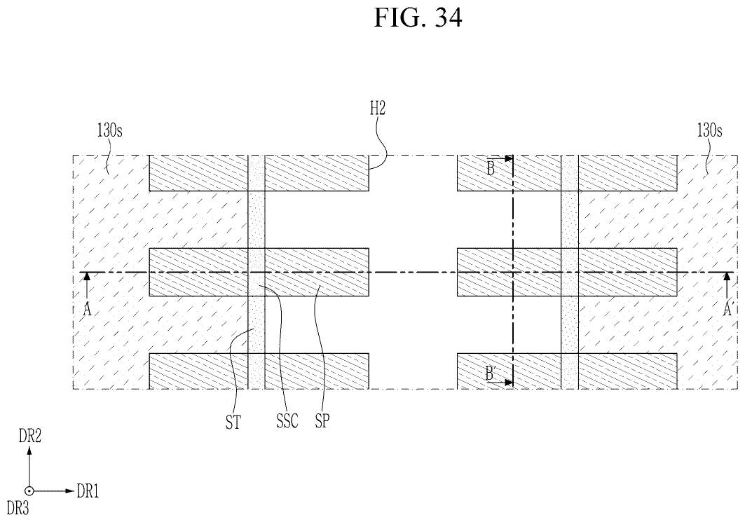

Referring to FIG. 34 to FIG. 36, the intermediate cell isolation layer 130m may be removed to expose portions of the plurality of semiconductor patterns SP that were covered by the intermediate cell isolation layer 130m.

First, a photoresist pattern may be formed on the upper surface of the intermediate cell isolation insulating layer 130 and the side cell isolation insulating layer 130s by using a photolithography process to define the region where a second hole H2 is formed. For example, the region corresponding to the opening of the photoresist pattern may be defined as the region where the second hole H2 is formed. By etching the intermediate cell isolation insulating layer 130m exposed by the opening of the photoresist pattern, the second hole H2 may be formed. For instance, the intermediate cell isolation insulating layer 130m may be etched until one side surface of the intermediate insulating layer ST in the first direction DR1 is exposed by the opening of the photoresist pattern.

For example, when the intermediate insulating layer ST is not formed, the intermediate cell isolation insulating layer 130m and the side cell isolation insulating layer 130s may not be distinguished. In this case, in the process of etching the cell isolation insulating layer 130 in the first direction DR1, the portions of the cell isolation insulating layer 130 positioned between the plurality of semiconductor patterns SP stacked in the third direction DR3 may not be uniformly etched in the first direction DR1. For instance, the portions of the cell isolation insulating layer 130 positioned between the plurality of semiconductor patterns SP stacked in the third direction DR3 may have a reduced amount of etching in the first direction DR1 as they are closer to the upper surface of the substrate 110. Accordingly, the side surfaces of the portions of the cell isolation insulating layer 130 positioned between the plurality of semiconductor patterns SP corresponding to the first direction DR1 may have an inclination rather than being aligned in the third direction DR3. For instance, the side surfaces in the first direction DR1 of the portions of the cell isolation insulating layer 130, which are positioned between the plurality of semiconductor patterns SP may become farther from the central axis of the second hole H2 in the third direction DR3 as they become distant from the upper surface of the substrate 110. Additionally, each of the side surfaces in the first direction DR1 of the portions of the cell isolation insulating layer 130 positioned between the plurality of semiconductor patterns SP may be non-planar and may have a recessed shape in the first direction DR1. When a subsequent process is conducted in the above-described example, the element characteristics may deteriorate and the characteristic variations between elements may occur.

In some implementations, the intermediate insulating layer ST may function as an etch stop layer in the process of etching a cell isolation insulating layer 130 in the first direction DR1. The process may continue to etch the cell isolation insulating layer 130 in the first direction DR1 until the side surface of the intermediate insulating layer ST along the first direction DR1 are exposed. Accordingly, the plurality of semiconductor patterns SP stacked in the third direction DR3 may be exposed to the same length in the first direction DR1. Moreover, since the side surface of the intermediate insulating layer ST between the plurality of semiconductor patterns SP is flat in the first direction DR1, the degradation of element characteristics and the dispersion between elements may be reduced as subsequent processes are carried out on the surface.

For example, as the cell isolation insulating layer 130 is removed, semiconductor patterns SP positioned between the plurality of sacrificial metal silicide patterns SSC that are spaced apart in the first direction DR1 may be exposed. For instance, semiconductor patterns SP positioned on one side in the first direction DR1 of the reference plane defined by the plurality of sacrificial metal silicide patterns SSC that are spaced apart and arranged along the third direction DR3 and second direction DR2, and surrounded by the intermediate insulating layer ST, may be exposed. The semiconductor patterns SP located on the opposite side in the first direction DR1 of the reference plane may be covered by the side cell isolation insulating layer 130s.

In some implementations, the remaining surfaces of the semiconductor pattern SP, except for the surface which contacts the sacrificial metal silicide pattern SSC, may be exposed. For example, one side surface of the semiconductor pattern SP along a first direction DR1, both side surfaces of the semiconductor pattern SP along a second direction DR2, and both side surfaces of the semiconductor pattern SP along a third direction DR3 may be exposed. The other side surface of the semiconductor pattern SP along the first direction DR1 may be covered by the sacrificial metal silicide pattern SSC.

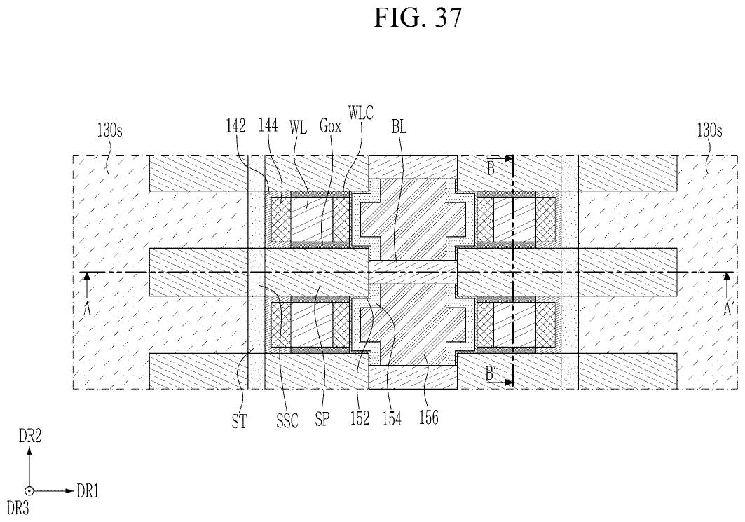

FIG. 37 to FIG. 39, a word line WL and a bit line BL may be formed.

First, a first interlayer dielectric layer 142, a second interlayer dielectric layer 144, and a third interlayer dielectric layer 146 may be formed on the substrate 110, the two adjacent intermediate insulating layers ST, and the plurality of semiconductor patterns SP. The first interlayer dielectric layer 142, the second interlayer dielectric layer 144, and the third interlayer dielectric layer 146 may be sequentially formed.

The first interlayer insulation layer 142, the second interlayer insulation layer 144, and the third interlayer insulation layer 146 may cover both side surfaces of the other end portion of the plurality of semiconductor patterns SP in the third direction DR3 and both side surfaces of the other end portion of the plurality of semiconductor patterns SP in the second direction DR2. The first interlayer insulation layer 142, the second interlayer insulation layer 144, and the third interlayer insulation layer 146 may cover one side surface of each of two adjacent intermediate insulation layers ST in the first direction DR1. The first interlayer insulation layer 142 may further cover the upper surface and the side surfaces of the substrate 110 positioned between two adjacent intermediate insulation layers ST. The third interlayer insulation layer 146 may extend in the first direction DR1 between the plurality of semiconductor patterns SP which are stacked to be spaced apart from each other in the third direction DR3.

The first interlayer dielectric layer 142, the second interlayer dielectric layer 144, and the third interlayer dielectric layer 146 each may include an insulating material. The second interlayer dielectric layer 144 may include a material having an etch selectivity with respect to a material of the first interlayer dielectric layer 142. The third interlayer dielectric layer 146 may include a material having an etch selectivity with respect to a material of the second interlayer dielectric layer 144. In some implementations, the first interlayer dielectric layer 142 and the third interlayer dielectric layer 146 may include the same material, but are not limited thereto. For example, the first interlayer dielectric layer 142 and the third interlayer dielectric layer 146 may include silicon oxide, and the second interlayer dielectric layer 144 may include silicon nitride, but are not limited thereto.

Subsequently, a gate insulating layer Gox, a word line WL, and a word line capping layer WLC may be formed. For example, the gate insulating layer Gox, the word line WL, and the word line capping layer WLC may be sequentially formed between the plurality of semiconductor patterns SP and the plurality of third interlayer insulation layers 146.

The gate insulating layer Gox may cover the portion positioned between both end portions of each of the plurality of semiconductor patterns SP in the first direction DR1. The gate insulating layer Gox may cover both side surfaces of each of the plurality of semiconductor patterns SP in the third direction DR3 and both side surfaces of each of the plurality of semiconductor patterns SP in the second direction DR2. The gate insulating layer Gox may cover both side surfaces of each of the plurality of third interlayer dielectric layers 146 in the third direction DR3.

The gate insulating layer Gox may include at least one of a high-k material, silicon oxide, silicon nitride, or silicon oxynitride. The high-k material may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate insulating layer Gox formed between the plurality of semiconductor patterns SP and the plurality of third interlayer dielectric layers 146, and the word line WL may fill the remaining space. The word line WL may cover the portion positioned between both end portions in a first direction DR1 of each of the plurality of semiconductor patterns SP in the second direction DR2 and the third direction DR3. The word line WL may extend in the second direction DR2. The gate insulating layer Gox may be positioned between the word line WL and the semiconductor pattern SP. The word line WL may be spaced apart from the semiconductor pattern SP by the gate insulating layer Gox.

In the described implementation, the word line WL has been described as surrounding the peripheral surface (e.g., both side surfaces in the third direction DR3 and both side surfaces in the second direction DR2) centering on the first direction DR1 of a certain region of the semiconductor pattern SP, but the implementation is not limited thereto. For instance, two word lines WL may be positioned spaced apart from each other on both side surfaces of the semiconductor pattern SP in the third direction DR3. Alternatively, one word line WL may also be positioned on only one side surface of the semiconductor pattern SP in the third direction DR3.

In some implementations, the plurality of word lines WL that are spaced apart and arranged in the third direction DR3 may be formed. The plurality of word lines WL may be further spaced apart and arranged in the first direction DR1. Each of the plurality of word lines WL may extend in the second direction DR2 across the plurality of semiconductor patterns SP that are spaced apart and arranged in the second direction DR2. The plurality of semiconductor patterns SP that are spaced apart and arranged in the second direction DR2 may be electrically connected with one word line WL.

The word line WL may include a conductive material. For example, the word line WL may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or combinations thereof.

The word line capping layer WLC may cover one side surface of the word line WL in the first direction DR1. Both side surfaces of the word line capping layer WLC in the third direction DR3 and both side surfaces of the word line capping layer WLC in the second direction DR2 may be covered by the gate insulating layer Gox.

The word line capping layer WLC may include an insulating material. For example, the word line capping layer WLC may include silicon nitride, but is not limited thereto.

Subsequently, a first insulating liner 152, a second insulating liner 154, and an isolation insulating layer 156 may be formed. First, the first insulating liner 152 and second insulating liner 154 may be formed sequentially on the plurality of semiconductor patterns SP, the word line capping layer WLC positioned between the plurality of semiconductor patterns SP, the gate insulating layer Gox, and the third interlayer dielectric layer 146. The first insulating liner 152 and second insulating liner 154 may cover both side surfaces in the third direction DR3 and both sides in the second direction DR2 of the one end portion in the first direction DR1 of each of the plurality of semiconductor patterns SP. The first insulating liner 152 and second insulating liner 154 may cover a portion of one side surface in the first direction DR1 of the one end portion in the first direction DR1 of each of the plurality of semiconductor patterns SP. The first insulating liner 152 and second insulating liner 154 may cover one side surface in the first direction DR1 of the gate insulating layer Gox, the word line capping layer WLC, and the third interlayer dielectric layer 146 between the plurality of semiconductor patterns SP.

Subsequently, an isolation insulating layer 156 may be formed covering the first insulating liner 152 and the second insulating liner 154. The isolation insulating layer 156 may fill the remaining space between the plurality of semiconductor patterns SP spaced apart in the first direction DR1 and between the plurality of word line capping layers WLC spaced apart in the first direction DR1, after forming the first insulating liner 152 and the second insulating liner 154.

The first insulating liner 152, the second insulating liner 154, and the isolation insulating layer 156 may include an insulating material. For example, each of the first insulating liner 152, the second insulating liner 154, and the isolation insulating layer 156 may include silicon oxide or silicon nitride, but are not limited thereto. The second insulating liner 154 may include a material having an etch selectivity relative to a material of the first insulating liner 152. The isolation insulating layer 156 may include a material having an etch selectivity relative to a material of the second insulating liner 154. For instance, the first insulating liner 152 and the isolation insulating layer 156 may include silicon oxide, and the second insulating liner 154 may include silicon nitride, but are not limited thereto.

Subsequently, a lower insulating layer 158 and a bit line BL may be formed. The bit line BL may be formed on the lower insulating layer 158. The lower insulating layer 158 may be positioned between the first interlayer dielectric layer 142 covering the upper surface and side surfaces of the substrate 110 and the bit line BL. The bit line BL may be spaced apart from the substrate 110 by the lower insulating layer 158 and the first interlayer dielectric layer 142.

The bit line BL may extend in the third direction DR3. The bit line BL may be spaced apart in the third direction DR3 and connected to one end portion of each of the plurality of semiconductor patterns SP stacked in the first direction DR1. For example, the bit line BL may contact one side surface of the semiconductor pattern SP in the first direction DR1. Between one side surface of the semiconductor pattern SP in the first direction DR1 and the bit line BL, the first insulating liner 152, the second insulating liner 154, and the isolation insulating layer 156 may not be positioned.

The bit line BL may be positioned between two semiconductor patterns SP spaced apart in the first direction DR1. In some implementations, the bit line BL may be connected to the two semiconductor patterns SP spaced apart in the first direction DR1, but is not limited thereto. For example, two bit lines BL may be formed between two semiconductor patterns SP spaced apart in the first direction DR1. In this case, the two semiconductor patterns SP spaced apart in the first direction DR1 may each be connected to different bit lines BL.

In some implementations, a plurality of bit lines BL spaced apart in a second direction DR2 may be formed. The isolation insulating layer 156 may be positioned between the plurality of bit lines BL spaced apart in the second direction DR2.

The bit line BL may include a conductive material. For instance, the bit line BL may include doped semiconductor materials such as doped silicon or doped germanium, conductive metal nitrides such as titanium nitride or tantalum nitride, metals such as tungsten, titanium, or tantalum, metal-semiconductor compounds such as tungsten silicide, cobalt silicide, or titanium silicide, or combinations thereof.

The lower insulating layer 158 may include an insulating material. For example, the lower insulating layer 158 may include silicon oxide, silicon nitride, silicon oxynitride, or combinations thereof, but is not limited thereto.

Hereinafter, the plurality of semiconductor patterns SP, the plurality of bit lines BL, the plurality of sacrificial metal silicide patterns SSC, the plurality of intermediate insulating layers ST, the plurality of word lines WL, and a various other insulating layers formed on the substrate 110 may be referred to as intermediate structures.

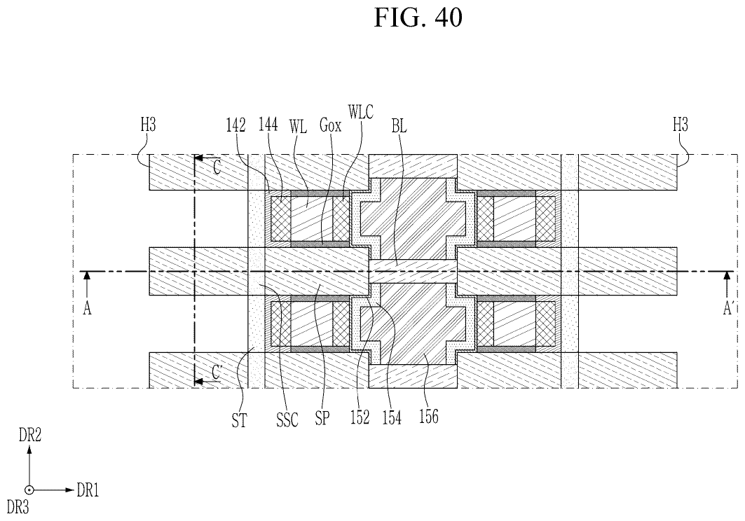

Referring to FIG. 40 to FIG. 42, the side cell isolation insulating layer 130s may be removed to expose a portion of the plurality of semiconductor patterns SP that were covered by the side cell isolation insulating layer 130s.

First, a photoresist pattern may be formed on the upper surface of the intermediate structure on the substrate 110 using a photolithography process to define the region where a third hole H3 is formed. For example, the region corresponding to the opening of the photoresist pattern may be defined as the region where the third hole H3 is formed. The third hole H3 may be formed by etching the side cell isolation insulating layer 130s exposed by the opening of the photoresist pattern. For instance, etching of the side cell isolation insulating layer 130s may be performed until one side surface of the intermediate insulating layer ST in the first direction DR1 is exposed by the opening of the photoresist pattern.

For example, in the case where the intermediate insulation layer ST is not formed, in the process of etching the side cell isolation insulation layer 130s in the first direction DR1, the parts of the side cell isolation insulation layer 130s positioned between the plurality of stacked semiconductor patterns SP in the third direction DR3 may not be evenly etched in the first direction DR1. For instance, the parts of the side cell isolation insulation layer 130s positioned between the plurality of stacked semiconductor patterns SP may have a reduced amount of etching in the first direction DR1 as they are closer to the upper surface of the substrate 110. As a result, the side surfaces of the parts of the side cell isolation insulation layer 130s positioned between the plurality of semiconductor patterns SP in the first direction DR1 may not be aligned in the third direction DR3 and may have an inclination. For example, as the side surfaces of the parts of the side cell isolation insulation layer 130s positioned between the plurality of semiconductor patterns SP in the first direction DR1 become farther from the upper surface of the substrate 110, they may become farther from the central axis in the third direction DR3 of the third hole H3. Additionally, each of the side surfaces of the parts of the side cell isolation insulation layer 130s positioned between the plurality of semiconductor patterns SP in the first direction DR1 may not be flat and may have a recessed shape in the first direction DR1. If subsequent processes are carried out in the aforementioned example, the element characteristics may deteriorate and differences in characteristics between elements may occur.

In some implementations, the intermediate insulating layer ST may serve as an etch stop layer in the process of etching the side cell isolation layer 130s in the first direction DR1. In the process of etching the side cell isolation layer 130s in the first direction DR1, the side cell isolation layer 130s may be etched until the side surface of the intermediate insulating layer ST in the first direction DR1 are exposed. Accordingly, the plurality of semiconductor patterns SP stacked in the third direction DR3 may be exposed to the same length in the first direction DR1. Since the side surface of the intermediate insulating layer ST in the first direction DR1 between the plurality of semiconductor patterns SP are flat, subsequent processes on the surface may reduce element characteristics degradation and distribution between elements.

In other words, the intermediate insulating layer ST may function as an etching stop layer in both directions in the process shown in FIG. 34 to FIG. 36 and the process shown in FIG. 40 to FIG. 42.

For example, as the side cell isolation insulating layer 130s is removed, semiconductor patterns SP positioned on the opposite side to one side where the bit line BL is positioned among both sides in the first direction DR1 of the plurality of sacrificial metal silicide patterns SSC may be exposed. For instance, semiconductor patterns SP positioned on the other side in the first direction DR1 of the reference plane defined by the plurality of sacrificial metal silicide patterns SSC spaced apart and arranged along a third direction DR3 and a second direction DR2, and the intermediate insulating layer ST surrounding them, may be exposed. The semiconductor patterns SP positioned on the other side in the first direction DR1 of the reference plane may be connected to the bit line BL.

In some implementations, the remaining surfaces of the semiconductor pattern SP, excluding the surface which contacts the sacrificial metal silicide pattern SSC, may be exposed. For example, one side surface of the semiconductor pattern SP in the first direction DR1, both side surfaces of the semiconductor pattern SP in the second direction DR2, and both side surfaces of the semiconductor pattern SP in the third direction DR3 may be exposed. The other side surface of the semiconductor pattern SP in the first direction DR1 may be covered by the sacrificial metal silicide pattern SSC.

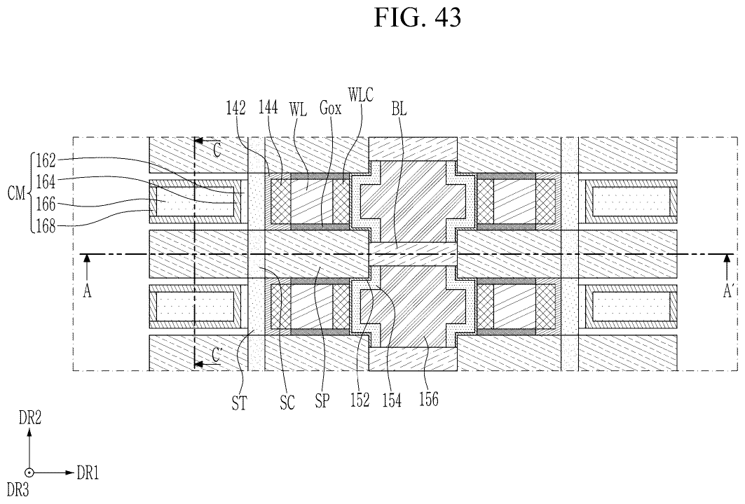

Referring to FIGS. 43 to 45, a capacitor mold CM may be formed on the substrate 110 and the intermediate insulating layer ST.

In some implementations, a capacitor mold CM may be formed to be spaced apart from the surface of the semiconductor pattern SP. The capacitor mold CM may include a first mold layer 162, a second mold layer 164, a third mold layer 166, and a fourth mold layer 168. The first mold layer 162, the second mold layer 164, the third mold layer 166, and the fourth mold layer 168 may be sequentially formed on the substrate 110 and the intermediate insulating layer ST.

The first mold layer 162 may cover a portion of the other side surface of the intermediate insulating layer ST in the first direction DR1. The first mold layer 162 may not cover a portion of the other side surface of the intermediate insulating layer ST in the first direction DR1 which is adjacent to the sacrificial metal silicide pattern SSC.

The second mold layer 164 may cover the first mold layer 162. The second mold layer 164 may include a vertical portion extending in the third direction DR3 and a horizontal portion extending from the vertical portion in the first direction DR1. The second mold layer 164 may extend in the first direction DR1 and may have the shape of a hollow cylinder. The first mold layer 162 and the second mold layer 164 may further cover the upper surface and side surfaces of the substrate 110.

The third mold layer 166 may cover the second mold layer 164. The third mold layer 166 may fill the inner space surrounded by the second mold layer 164. The third mold layer 166 may be surrounded by the second mold layer 164.

The fourth mold layer 168 may cover the third mold layer 166. The fourth mold layer 168 may cover one side surface of the third mold layer 166 in a first direction DR1. The other side surface of the third mold layer 166 in the first direction DR1 may be covered by the second mold layer 164.

The first mold layer 162, the second mold layer 164, the third mold layer 166, and the fourth mold layer 168 may each include an insulating material. The second mold layer 164 may include a material having an etch selectivity relative to a material of the first mold layer 162. The third mold layer 166 may include a material having an etch selectivity relative to a material of the second mold layer 164. The fourth mold layer 168 may include a material having an etch selectivity relative to a material of the third mold layer 166. In some implementations, the first mold layer 162 and the third mold layer 166 may include the same first material, and the second mold layer 164 and the fourth mold layer 168 may include the same second material. For example, the first material may include silicon nitride, and the second material may include silicon oxide, but is not limited thereto.

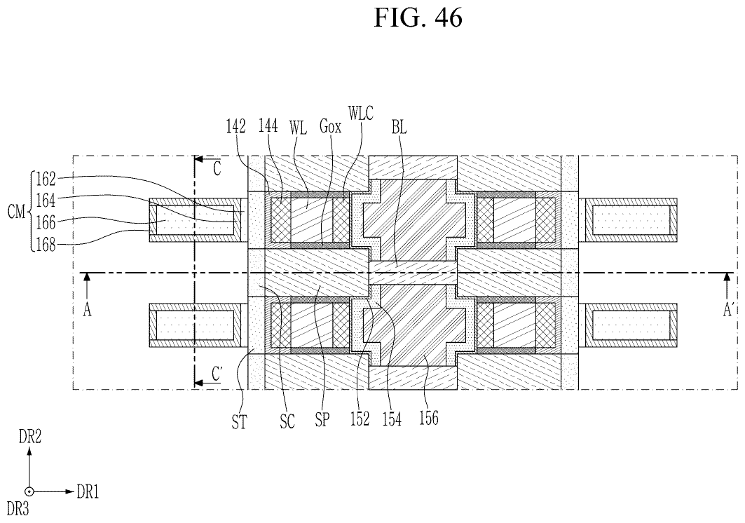

Referring to FIG. 46 to FIG. 48, semiconductor patterns SP positioned on the opposite side of one side where the bit line BL is positioned among both sides of the sacrificial metal silicide pattern SSC in the first direction DR1 may be removed. For example, using a material with a high etch selectivity for the semiconductor pattern SP with respect to the intermediate insulating layer ST, the sacrificial metal silicide pattern SSC, and the capacitor mold CM, only the semiconductor pattern SP may be selectively removed. Accordingly, the opposite surface of one side surface covered by the semiconductor pattern SP connected to the bit line BL among both side surfaces of the sacrificial metal silicide pattern SSC in the first direction DR1 may be exposed.

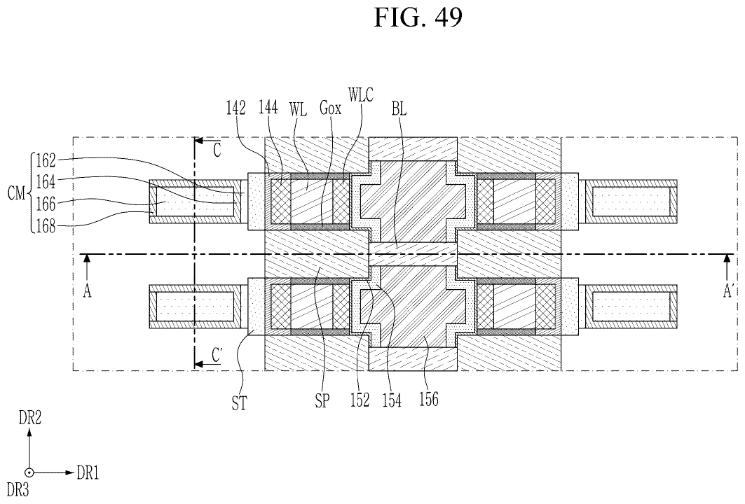

Referring to FIG. 49 to FIG. 51, the sacrificial metal silicide pattern SSC may be removed. For example, a material with a high etch selectivity ratio for the sacrificial metal silicide pattern SSC relative to the intermediate insulating layer ST, the semiconductor pattern SP, and the capacitor mold CM may be used to selectively remove only the sacrificial metal silicide pattern SSC. For instance, low aluminum loss (LAL) etchant may be used to remove the sacrificial metal silicide pattern SSC, but this is not limited thereto, and the material for etching the sacrificial metal silicide pattern SSC may be variously changed.

As the sacrificial metal silicide pattern SSC is removed, the other end portion of the plurality of semiconductor patterns SP in the first direction DR1, having one end portions of the plurality of semiconductor patterns SP in the first direction DR1 connected to the bit line BL, may be exposed.

For example, when the sacrificial metal silicide pattern SSC is not formed, the other end portions of the plurality of semiconductor patterns SP in the first direction DR1 may be covered by the intermediate insulating layer ST. In this case, during the process of opening the other end portions of the plurality of semiconductor patterns SP in the first direction DR1, it may be difficult to accurately etch and remove only the portion of the intermediate insulating layer ST covering the semiconductor pattern SP. For instance, when etching and removal extend to the portion of the intermediate insulating layer ST covering the first interlayer dielectric layer 142, a bridge defect may occur where the capacitors CP of adjacent semiconductor patterns SP become electrically connected during the subsequent capacitor CP forming. To prevent such bridge defects, the sacrificial metal silicide pattern SSC is formed to cover the other end portion of the semiconductor pattern SP in the first direction DR1 to be opened in a subsequent process, and by selectively removing the sacrificial metal silicide pattern SSC, only the necessary portion (the other end portion of the semiconductor pattern SP in the first direction DR1) can be accurately opened.

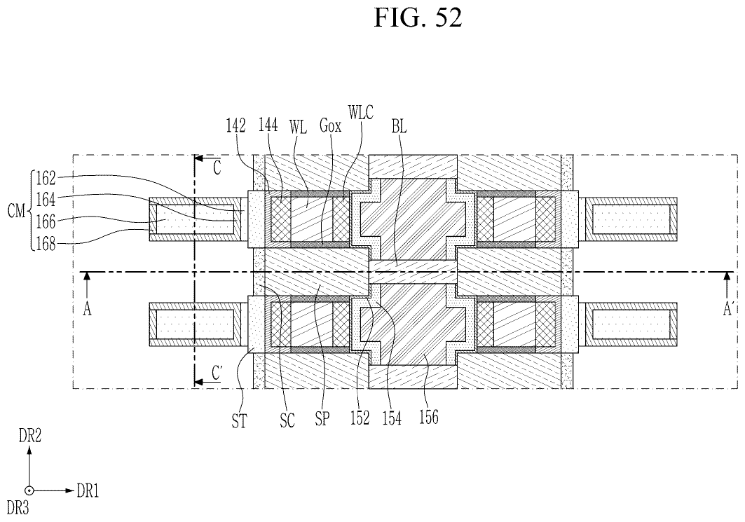

Referring to FIG. 52 to FIG. 54, a metal silicide pattern SC may be formed on the other side surface of each of the plurality of semiconductor patterns SP in the first direction DR1. For example, the semiconductor pattern SP may include silicon. Initially, after depositing a metal layer to cover the plurality of semiconductor patterns SP, the intermediate insulating layer ST, and the capacitor mold CM, a silicide reaction may be induced in the portion of the metal layer contacting the semiconductor pattern SP through heat treatment. Subsequently, by selectively removing the portion of the metal layer where the silicide reaction has not occurred, the metal silicide pattern SC may be formed on each of the semiconductor patterns SP.

In some implementations, a plurality of metal silicide patterns SC may be positioned on the other side surfaces of the plurality of semiconductor patterns SP in accordance with a first direction DR1. The metal silicide pattern SC may cover the other side surfaces of the semiconductor pattern SP in accordance with the first direction DR1. Intermediate insulating layer ST may be positioned on both sides of the metal silicide pattern SC in accordance with a third direction DR3 and both sides in accordance with a second direction DR2 of the metal silicide pattern SC. Both side surfaces of the metal silicide pattern SC in accordance with the third direction DR3 and both side surfaces of the metal silicide pattern SC in accordance with the second direction DR2 may be covered by the intermediate insulating layer ST.

In some implementations, both side surfaces of the metal silicide pattern SC in the third direction DR3 and both side surfaces of the metal silicide pattern SC in the second direction DR2 may contact the intermediate insulating layer ST, but are not limited thereto. For example, as illustrated in FIG. 6, both side surfaces of the metal silicide pattern SC in the third direction DR3 and both side surfaces of the metal silicide pattern SC in the second direction DR2 may be spaced apart from the intermediate insulating layer ST.

In some implementations, the width of the metal silicide pattern SC in the third direction DR3 may be the same as the width of the semiconductor pattern SP in the third direction DR3. The width of the metal silicide pattern SC in the second direction DR2 may be the same as the width of the semiconductor pattern SP in the second direction DR2. However, the implementation is not limited thereto. For example, as shown in FIG. 6 and FIG. 7, the metal silicide pattern SC may be formed to further cover both side surfaces of the semiconductor pattern SP in the third direction DR3 and both side surfaces in the second direction DR2. In this case, the width of the metal silicide pattern SC in the third direction DR3 may be greater than the width of the semiconductor pattern SP in the third direction DR3. The width of the metal silicide pattern SC in the second direction DR2 may be greater than the width of the semiconductor pattern SP in the second direction DR2.

In some implementations, the width of the metal silicide pattern SC in the first direction DR1 may be smaller than the width of the intermediate insulating layer ST in the first direction DR1, but is not limited thereto. For example, the width of the metal silicide pattern SC in the first direction DR1 may be the same as the width of the intermediate insulating layer ST in the first direction DR1 or greater than the width of the intermediate insulating layer ST in the first direction DR1.

The metal silicide pattern SC may include a metal silicide material. The work function of the metal silicide pattern SC may have a value between the work function of the material of the first electrode 171 and the work function of the material of the semiconductor pattern SP. The metal silicide pattern SC may reduce the work function difference between the material of the first electrode 171 and the material of the semiconductor pattern SP to lower the contact resistance between the semiconductor pattern SP and the capacitor CP. For example, the metal silicide pattern SC may include cobalt silicide, titanium silicide, nickel silicide, or titanium silicon nitride, but is not limited thereto.

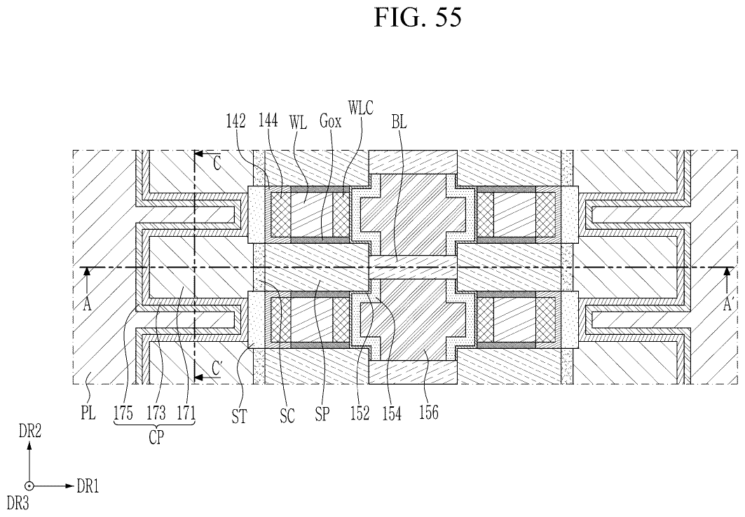

Referring to FIG. 55 to FIG. 57, the capacitor mold CM may be removed, and a capacitor CP may be formed.

First, a first electrode 171 may be formed. For example, after depositing a first electrode material layer on the metal silicide pattern SC, the intermediate insulating layer ST, and the capacitor mold CM, a portion of the first electrode material layer covering one side surface of the capacitor mold CM in the first direction DR1 may be removed through an etch-back process, thereby forming a plurality of first electrodes 171. The plurality of first electrodes 171 may be spaced apart in the second direction DR2 and the third direction DR3 by the capacitor mold CM.

Each of the plurality of first electrodes 171 may contact one side surface of the metal silicide pattern SC in the first direction DR1. The other side surface of the metal silicide pattern SC in the first direction DR1 may contact the semiconductor pattern SP. The first electrode 171 may cover a portion of the intermediate insulating layer ST not covered by the capacitor mold CM. The first electrode 171 may cover a portion of one side surface of the intermediate insulating layer ST in the first direction DR1 positioned on both sides of the metal silicide pattern SC.

The width of the metal silicide pattern SC in the first direction DR1 may be smaller than the width of the intermediate insulating layer ST in the first direction DR1, such that some portions of the surfaces facing each other in the third direction DR3 and some portions of the surfaces facing each other in the second direction DR2 of the intermediate insulating layer ST positioned on both sides of the metal silicide pattern SC may be exposed. The first electrode 171 may cover some portions of the surfaces facing each other in the third direction DR3 and some portions of the surfaces facing each other in the second direction DR2 of the intermediate insulating layer ST positioned on both sides of the metal silicide pattern SC. Some portions of the first electrode 171 may be surrounded by the intermediate insulating layer ST in the third direction DR3 and the second direction DR2.

Subsequently, the capacitor mold CM may be removed.

Subsequently, a dielectric layer 173 and a second electrode 175 may be formed sequentially. The dielectric layer 173 and the second electrode 175 may be formed to conformally cover the plurality of first electrodes 171. The dielectric layer 173 may cover one side surface of the plurality of first electrodes 171 in the first direction DR1, both side surfaces of the plurality of first electrodes 171 in the third direction DR3, and both side surfaces of the plurality of first electrodes 171 in the second direction DR2. The dielectric layer 173 may further cover one side surface of the intermediate insulating layer ST in the first direction DR1. The second electrode 175 may cover the dielectric layer 173. The second electrode 175 may be spaced apart from the plurality of first electrodes 171 by the dielectric layer 173.

The first electrode 171, the dielectric layer 173, and the second electrode 175 may form a capacitor CP. In some implementations, the plurality of capacitors CP including the plurality of the first electrodes 171 respectively may be formed. The plurality of capacitors CP may be connected to the plurality of semiconductor patterns SP respectively. Each first electrode 171 of the plurality of capacitors CP may be connected to the semiconductor pattern SP by the metal silicide pattern SC.

The plurality of capacitors CP may be arranged spaced apart in the third direction DR3 and the second direction DR2. The plurality of capacitors CP may include the plurality of first electrodes 171 arranged spaced apart in the third direction DR3 and the second direction DR2. The plurality of first electrodes 171 arranged spaced apart in the third direction DR3 and the second direction DR2 may be covered by a single dielectric layer 173 and a single second electrode 175. The dielectric layer 173 of each of the plurality of capacitors CP arranged spaced apart in the third direction DR3 and the second direction DR2 may be connected to each other. The second electrode 175 of each of the plurality of capacitors CP arranged spaced apart in the third direction DR3 and the second direction DR2 may be connected to each other.

Subsequently, a plate electrode PL may be formed. For example, the plate electrode PL may fill the remaining space opposite to one side where the bit line BL is positioned, based on the intermediate insulating layer ST, with the first electrode 171, the dielectric layer 173, and the second electrode 175 being formed. The plate electrode PL may cover the second electrode 175 of the plurality of capacitors CP arranged along the second direction DR2 and third direction DR3. The plate electrode PL may be connected to the plurality of capacitors CP arranged along the second direction DR2 and third direction DR3.

In some implementations, the plate electrode PL may include a first portion PL_1 extending in the third direction DR3 and the second direction DR2, and a second portion PL_2 extending from the first portion PL_1 in the first direction DR1. The first portion (PL_1) may have a wall shape extending in the third direction DR3 and the second direction DR2. The second portion PL_2 may surround the first electrodes 171 of the plurality of capacitors CP arranged along the second direction DR2 and the third direction DR3.

However, the implementation is not limited thereto, and for example, as shown in FIG. 8 and FIG. 9, the structure and shape of the capacitor CP and the plate electrode PL may be variously modified.

The first electrode 171, the second electrode 175, and the plate electrode PL may each include a conductive material. The first electrode 171, the second electrode 175, and the plate electrode PL each may include at least one of a metallic material such as titanium, tantalum, tungsten, copper, or aluminum, a conductive metallic nitride such as titanium nitride or tantalum nitride, or a doped semiconductor material such as doped silicon or doped germanium. The first electrode 171 and the second electrode 175 may include the same material, and the plate electrode PL may include a different material from a material of the first electrode 171 and a material of the second electrode 175. For example, the first electrode 171 and the second electrode 175 may include titanium nitride, and the plate electrode 194 may include doped silicon germanium.

The dielectric layer 173 may include at least one of a dielectric, a ferroelectric, or an antiferroelectric. The dielectric may include a high-k material. For example, the dielectric may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof.

A semiconductor device according to some implementations may have a symmetrical structure with respect to the bit line BL extending in the third direction DR3. Both side surfaces of the bit line BL in the first direction DR1 may each be connected to one end portion of the semiconductor pattern SP in the first direction DR1. The other end portion of the semiconductor pattern SP in the first direction DR1 may be connected to the capacitor CP. The metal silicide pattern SC may be positioned between the other end portion of the semiconductor pattern SP in the first direction DR1 and the capacitor CP. The intermediate insulating layer ST may be positioned on both sides of the metal silicide pattern SC in the third direction DR3 and on both sides of the metal silicide pattern SC in the second direction DR2. The word line WL may be positioned on both sides of each semiconductor pattern SP in the third direction DR3. The word line WL may extend in the second direction DR2.

FIG. 40 to FIG. 57 describe the explanation based on one side of the bit line BL in the first direction DR1, but the same process may also proceed simultaneously on the other side of the bit line BL in the first direction DR1.

The implementations of the present disclosure have been described in detail above, but the scope of rights of the disclosure is not limited thereto. Instead, various modifications and improvements by those skilled in the art, utilizing the basic concept of the disclosure defined in the following claims, are also included within the scope of rights of the disclosure.

What is claimed is:

1. A semiconductor device comprising:
a substrate,
a plurality of semiconductor patterns stacked spaced apart from each other on the substrate,
a bit line connected to a first end portion of the plurality of semiconductor patterns in a first direction, and extending in a direction perpendicular to an upper surface of the substrate,
a word line overlapping each semiconductor pattern in the plurality of semiconductor patterns in the direction perpendicular to the upper surface of the substrate, and extending in a second direction intersecting the first direction,
a capacitor connected to a second end portion of each semiconductor pattern in the plurality of semiconductor patterns in the first direction,
a metal silicide pattern between each semiconductor pattern and the capacitor, and
an intermediate insulating layer overlapping the metal silicide pattern in the direction perpendicular to the upper surface of the substrate.

2. The semiconductor device of claim 1,
wherein the metal silicide pattern contacts the second end portion of each semiconductor pattern in the first direction, and
wherein the intermediate insulating layer is on an upper surface and a lower surface of the metal silicide pattern.

3. The semiconductor device of claim 2, wherein the upper surface and the lower surface of the metal silicide pattern contact the intermediate insulating layer.

4. The semiconductor device of claim 2, wherein the capacitor includes a portion between the upper surface of the metal silicide pattern and the intermediate insulating layer, and between the lower surface of the metal silicide pattern and the intermediate insulating layer.

5. The semiconductor device of claim 2, wherein a first side surface of the metal silicide pattern in the first direction that contacts each semiconductor pattern is aligned with a first side surface of the intermediate insulating layer in the first direction in the direction perpendicular to the upper surface of the substrate and.

6. The semiconductor device of claim 2, wherein each semiconductor pattern includes a portion overlapping the intermediate insulating layer in the direction perpendicular to the upper surface of the substrate.

7. The semiconductor device of claim 6, wherein the metal silicide pattern includes a portion between each semiconductor pattern and the intermediate insulating layer.

8. The semiconductor device of claim 1, comprising a plate electrode connected to a plurality of capacitors, wherein each capacitor of the plurality of capacitors is connected to a respective semiconductor pattern of the plurality of semiconductor patterns,
wherein each capacitor the plurality of capacitors comprises a respective first electrode that contacts the metal silicide pattern, a respective second electrode on the respective first electrode, and a respective dielectric layer between the respective first electrode and the respective second electrode, and
wherein the respective dielectric layer of the plurality of capacitors are connected together, and the respective second electrodes of the plurality of capacitors are connected together.

9. The semiconductor device of claim 8, wherein, for each capacitor of the plurality of capacitors, the respective dielectric layer of the capacitor contacts a first side of the intermediate insulating layer in the first direction.

10. The semiconductor device of claim 9,
wherein, for each capacitor of the plurality of capacitors, the respective first electrode of the capacitor has a column shape extending in the first direction, and the respective first electrode is surrounded by the respective dielectric layer and the respective second electrode of the capacitor, and
wherein the plate electrode comprises a first portion extending in the direction perpendicular to the upper surface of the substrate at a first side in the first direction of the respective first electrodes of the plurality of capacitors, and a second portion extending from the first portion in the first direction and between the respective first electrodes.

11. The semiconductor device of claim 9, wherein, for each capacitor of the plurality of capacitors, the respective first electrode has a shape of a hollow cylinder, and
wherein the respective dielectric layer and the respective second electrode of the capacitor cover an outer surface and an inner surface of the respective first electrode.

12. The semiconductor device of claim 8, wherein, for each capacitor of the plurality of capacitors, the respective dielectric layer is spaced apart from a first side of the intermediate insulating layer in the first direction.

13. The semiconductor device of claim 12, wherein, for each capacitor of the plurality of capacitors, the respective first electrode has a shape of a hollow cylinder, and
wherein the respective dielectric layer and the respective second electrode of the capacitor cover an inner side of the respective first electrode.

14. The semiconductor device of claim 1, wherein the intermediate insulating layer comprises a first material that is different from a second material of each semiconductor pattern.

15. A semiconductor device comprising:
a substrate,
a plurality of semiconductor patterns stacked spaced apart from each other on the substrate,
a bit line connected to a first end portion of the plurality of semiconductor patterns in a first direction, and extending in a direction perpendicular to an upper surface of the substrate,
a word line overlapping each semiconductor pattern in the plurality of semiconductor patterns in the direction perpendicular to the upper surface of the substrate, and extending in a second direction intersecting the first direction,
a capacitor connected to a second end portion of each semiconductor pattern in the plurality of semiconductor patterns in the first direction,
a metal silicide pattern between each semiconductor pattern and the capacitor, and
an intermediate insulating layer surrounding the metal silicide pattern.

16. The semiconductor device of claim 15, wherein the direction perpendicular to the upper surface of the substrate is a third direction, and
wherein the intermediate insulating layer is on two opposite sides of the metal silicide pattern in the second direction and on two opposite sides of the metal silicide pattern in the third direction.

17. The semiconductor device of claim 15, wherein the metal silicide pattern contacts the intermediate insulating layer.

18. The semiconductor device of claim 15, wherein the capacitor comprises a portion between the metal silicide pattern and the intermediate insulating layer.

19. The semiconductor device of claim 15, wherein the metal silicide pattern contacts each semiconductor pattern in the first direction and in the direction perpendicular to the upper surface of the substrate.

20. A semiconductor device comprising:
a substrate,
an intermediate insulating layer extending in a direction perpendicular to an upper surface of the substrate,
a plurality of metal silicide patterns spaced apart by the intermediate insulating layer,
a plurality of semiconductor patterns respectively connected to a first side surface of the plurality of metal silicide patterns in a first direction,
a bit line connected to a first end portion of the plurality of semiconductor patterns in the first direction, and extending in the direction perpendicular to the upper surface of the substrate,
a plurality of word lines respectively adjacent to the plurality of semiconductor patterns, and extending in a second direction intersecting the first direction, and
a plurality of capacitors respectively connected to a second side surface of the plurality of metal silicide patterns in the first direction,
wherein the intermediate insulating layer is on two opposite sides of each of the plurality of metal silicide patterns in the second direction and two opposite sides of each of the plurality of metal silicide patterns in the direction perpendicular to the upper surface of the substrate.
